(19) United States
(12) Patent Application Publication
(10) Pub. No.: US 2025/0149506 A1
(43) Pub. Date: May 8, 2025

(54) POWER ELECTRONICS PACKAGE HAVING SIGNAL CONNECTIONS FOR MULTIPLE POWER DEVICES

(71) Applicant: WOLFSPEED, INC., Durham, NC (US)

(72) Inventor: Kirill Klein, Berlin (DE)

(21) Appl. No.: 18/502,911

(22) Filed: Nov. 6, 2023

(51) Int. Cl. H01L 25/065; H01L 23/00; H01L 23/495

(52) U.S. Cl. CPC H01L 25/0655; H01L 23/49513; H01L 24/08; H01L 24/48; H01L 2224/08145; H01L 2224/08155; H01L 2224/48139; H01L 2224/48157; H01L 2924/014; H01L 2924/13055; H01L 2924/13062; H01L 2924/13091

(57) ABSTRACT

A power package includes a power substrate; one or more power devices arranged on the power substrate; an assembly having a top surface, first sides, and second sides; power contacts; and signal contacts. Additionally, the signal contacts are configured on the top surface, in the top surface, and/or to extend from the top surface. Furthermore, the signal contacts are arranged in a middle section of the top surface between the second sides.

### BACKGROUND OF THE DISCLOSURE

Power electronics packages typically implement one or more power devices, such as Silicon Carbide (SiC) power devices, which offer a high level of performance benefits, including high voltage blocking, low on-resistance, high current, fast switching, low switching losses, high junction temperatures, and high thermal conductivity.

However, what is needed is power electronics packages implementing layouts, structures, and/or configurations that can operate commensurate with the high level performance of the power devices implemented by the power electronics packages.

### SUMMARY OF THE DISCLOSURE

In one aspect, a power package includes a power substrate. The power package also includes one or more power devices arranged on the power substrate. The package furthermore includes an assembly having a top surface, first sides, and second sides. The package in addition includes power contacts. The package moreover includes signal contacts. The package also includes where the signal contacts are configured to extend on the top surface, in the top surface, and/or to extend from the top surface. The package furthermore includes where the signal contacts are arranged in a middle section of the top surface between the second sides.

In one aspect, a power package includes a power substrate. The power package also includes one or more power devices arranged on the power substrate. The package furthermore includes an assembly having a top surface, first sides, and second sides. The package in addition includes power contacts. The package moreover includes signal contacts. The package also includes where the power substrate may include a die attach region where the one or more power devices are arranged on a surface of the power substrate. The package furthermore includes where the signal contacts are arranged above the die attach region of the one or more power devices.

In one aspect, a power package includes a power substrate. The power package also includes one or more power devices arranged on the power substrate. The package furthermore includes an assembly having a top surface, first sides, and second sides. The package in addition includes power contacts. The package moreover includes signal contacts. The package also includes signal interconnections configured to connect the signal contacts to respective connections on the one or more power devices to provide signals to the one or more power devices. The package furthermore includes where the power package has an overall gate-loop inductance that is generated based on a construction and configuration of the signal contacts and/or the signal interconnections. The package in addition includes where the signal contacts and/or the signal interconnections are constructed and configured to have a similar overall gate-loop inductance, where a similar overall gate-loop inductance is within 0%-6% in inductance.

In one aspect, a power package includes a power substrate. The power package also includes one or more power devices arranged on the power substrate. The package furthermore includes an assembly having a top surface, first sides, and second sides. The package in addition includes power contacts. The package moreover includes signal contacts. The package also includes signal interconnections configured to connect the signal contacts to respective connections on the one or more power devices to provide signals to the one or more power devices. The package furthermore includes where the signal interconnections each have a similar length from the signal contacts to the one or more power devices, where a similar length is within 0%-20% in length.

In one aspect, a power package includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes signal interconnections configured to connect the signal contacts to respective connections on the one or more power devices to provide signals to the one or more power devices. The power package furthermore includes where the signal contacts and/or the signal interconnections are constructed and configured to have a similar overall gate-loop inductance, where a similar overall gate-loop inductance is within 3 nH.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a top side perspective view of a power package according to aspects of the disclosure.

FIG. 2 illustrates a side view of the power package according to FIG. 1.

FIG. 3 illustrates a front side view of the power package according to FIG. 1.

FIG. 4 illustrates a cross-sectional side view of the power package according to FIG. 1.

FIG. 5 illustrates a cross-sectional front side view of the power package according to FIG. 1.

FIG. 6 illustrates another cross-sectional front side view of the power package according to FIG. 1.

FIG. 7 illustrates another cross-sectional front side view of the power package according to FIG. 1.

FIG. 8 illustrates a top view of the power package according to FIG. 1.

FIG. 9 illustrates a top view of the power package according to FIG. 1.

FIG. 10 illustrates a partial schematic topology of the power package according to aspects of the disclosure.

FIG. 11 illustrates a top side perspective view of a power package according to aspects of the disclosure.

FIG. 12 illustrates a side view of the power package according to FIG. 11.

FIG. 13 illustrates a front side view of the power package according to FIG. 11.

FIG. 14 illustrates a cross-sectional side view of the power package according to FIG. 11.

FIG. 15 illustrates a cross-sectional front side view of the power package according to FIG. 11.

FIG. 16 illustrates another cross-sectional front side view of the power package according to FIG. 11.

FIG. 17 illustrates another cross-sectional front side view of the power package according to FIG. 11.

FIG. 18 illustrates a top view of the power package according to FIG. 11.

FIG. 19 illustrates a top view of the power package according to FIG. 11.

FIG. 20 illustrates a top side perspective view of a power package according to aspects of the disclosure.

FIG. 21 illustrates a side view of the power package according to FIG. 20.

FIG. 22 illustrates a front side view of the power package according to FIG. 20.

FIG. 23 illustrates a cross-sectional side view of the power package according to FIG. 20.

FIG. 24 illustrates a cross-sectional front side view of the power package according to FIG. 20.

FIG. 25 illustrates a top side perspective view of a power package according to aspects of the disclosure.

FIG. 26 illustrates a side view of the power package according to FIG. 25.

FIG. 27 illustrates a front side view of the power package according to FIG. 25.

FIG. 28 illustrates a cross-sectional side view of the power package according to FIG. 25.

FIG. 29 illustrates a cross-sectional front side view of the power package according to FIG. 25.

FIG. 30 illustrates a top side perspective view of a combined configuration of multiple implementations of the power package according to aspects of the disclosure.

FIG. 31 illustrates a top side perspective view of a power package according to aspects of the disclosure.

FIG. 32 illustrates a related art implementation of a power electronics package.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

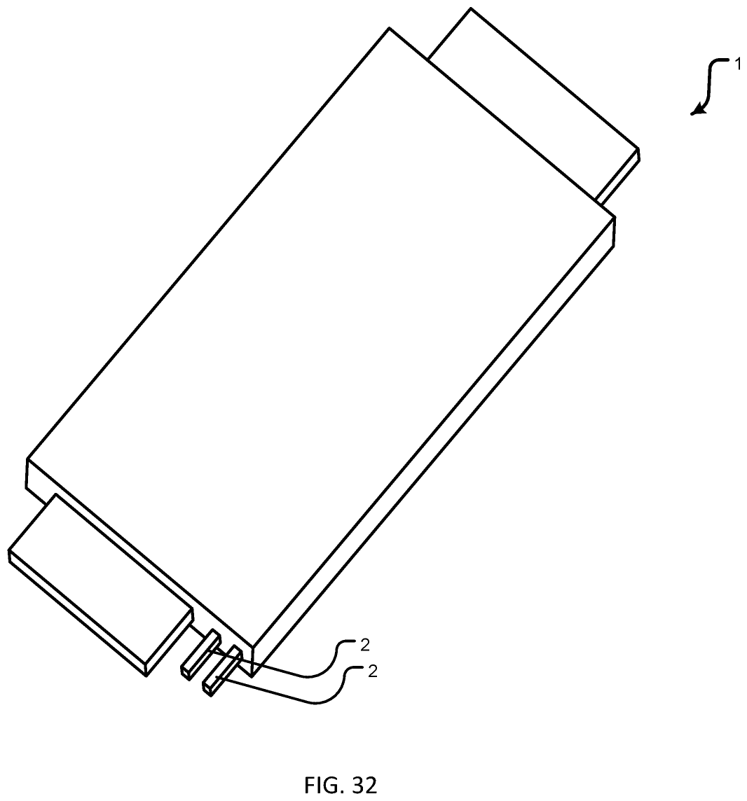

FIG. 32 illustrates a related art implementation of a power electronics package 1 that may be implemented with one or more dies and topologies. For example, the power electronics package 1 may be implemented as a single-switch package with up-to four dies. As further illustrated in FIG. 32, gate and kelvin source connections 2 are located in or at a corner of the power electronics package 1. This has several disadvantages: (1) A distance and/or connection length from the gate and kelvin source connections 2 to each die is different and therefore a gate-loop inductance for each die is different. This has negative impact on switching performance of the power electronics package 1. (2) The corner location of the gate and kelvin source connections 2 requires interconnection of gates and sources of the dies to the corner and it requires additional space within the power electronics package 1. (3) The gate and kelvin source connections 2 are located on a side of the power electronics package 1 and therefore a coupling of magnetic fields from drain-source currents into the gate-loop is higher. This cause limitations in switching speed the power electronics package 1.

In aspects, the disclosed power electronics package places the gate and Kelvin-source pins in a middle section or middle of the power electronics package, so that distance to all dies will be the same or substantially the same.

In aspects, the disclosed power electronics package may be configured such that all dies will have the same or nearly same gate-loop inductance. Moreover, the disclosed power electronics package is configured such that an overall gate-loop inductance is lower. Further, the disclosed power electronics package is configured such that half of the drain-source current will flow on one side and another half on the other side. Consequently, magnetic fields in the middle will cancel each other.

In aspects, the disclosed power electronics package may be configured such that there may be any number of pins including two pins, three pins, four pins or more. Additional pins may be implemented in the disclosed power electronics package for additional functions of the disclosed power electronics package.

In aspects, the disclosed power electronics package may include different arrangements of the pins. In aspects, the pins may be arranged on an axis or substantially on an axis along a long side. In aspects, the pins may be arranged on an axis or substantially on an axis along a short side or even shifted. In aspects, the pins may be located relatively close to each other and in the middle section or middle of the package.

In aspects, the pins may be implemented with an appearance similar to a standard surface mount device (SMD) header. In aspects, the pins may have ends compatible to press-fit technology or be any other type of pins. In aspects, the header may be configured as a receptacle, may be configured as a female type connection header, and/or may be implemented as control connectors.

In aspects, the disclosed power electronics package may be configured with a pin joint. The pin joint may be configured as a joint to a substrate, such as a ceramic substrate inside a mold compound of the power electronics package. In aspects, the disclosed power electronics package may be over-molded or the pins can be placed in holes or blind holes and/or openings of the mold of the power electronics package.

In aspects, the disclosed power electronics package may be configured as a single piece construction. In aspects, the disclosed power electronics package may be joined to a multiple packages combined into a single module. In aspects, the disclosed power electronics package may be configured 2×2=4 packages combined into a power module. In aspects, the disclosed power electronics package may include four packages added as two in a row and two in parallel as single module.

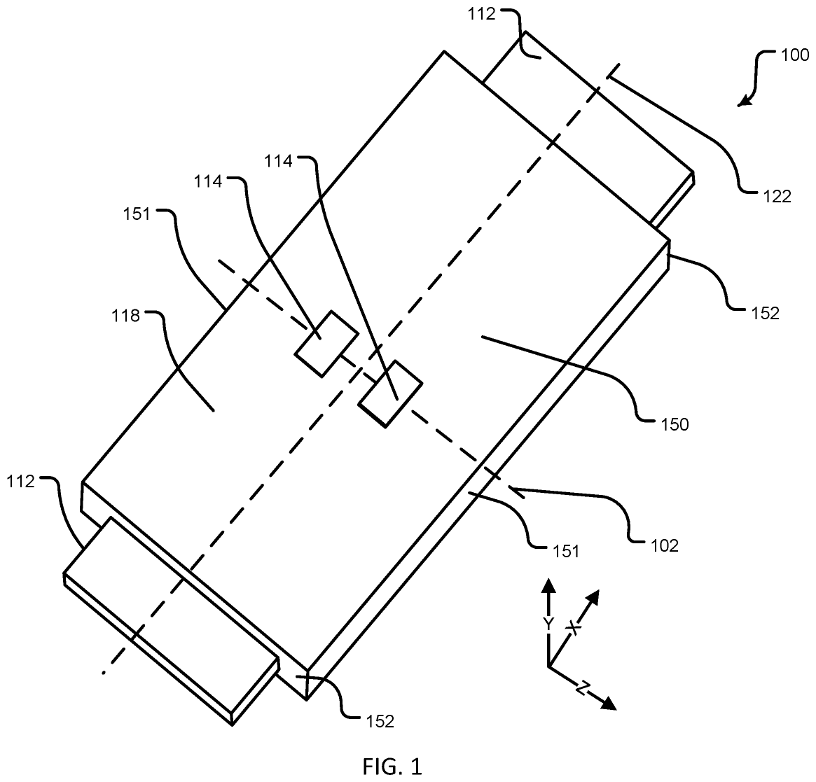

FIG. 1 illustrates a top side perspective view of a power package according to aspects of the disclosure.

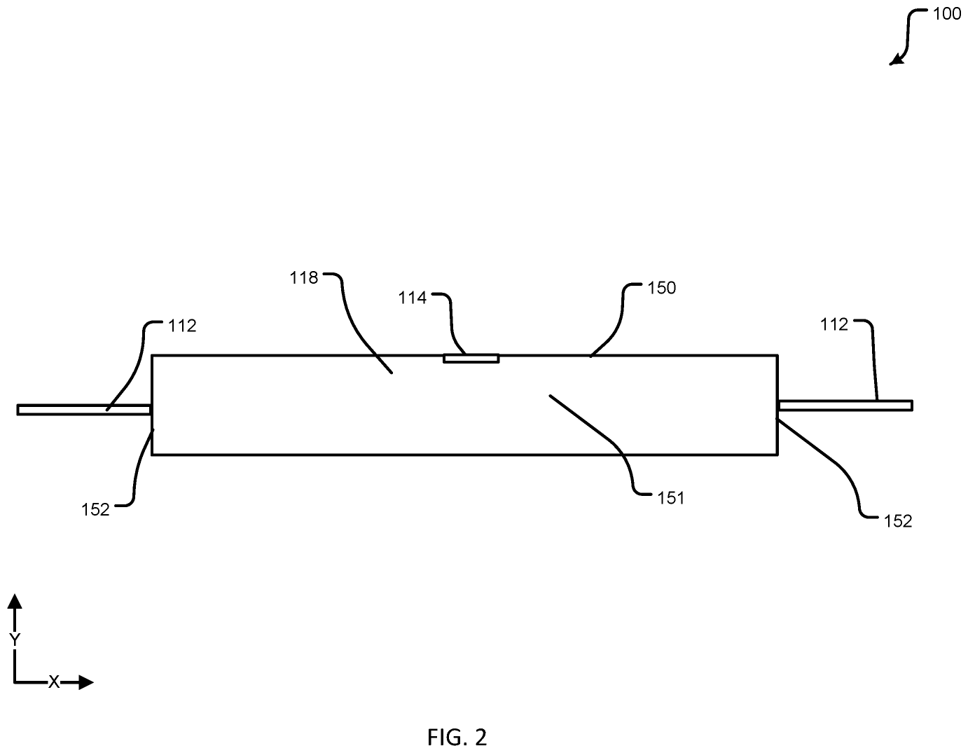

FIG. 2 illustrates a side view of the power package according to FIG. 1.

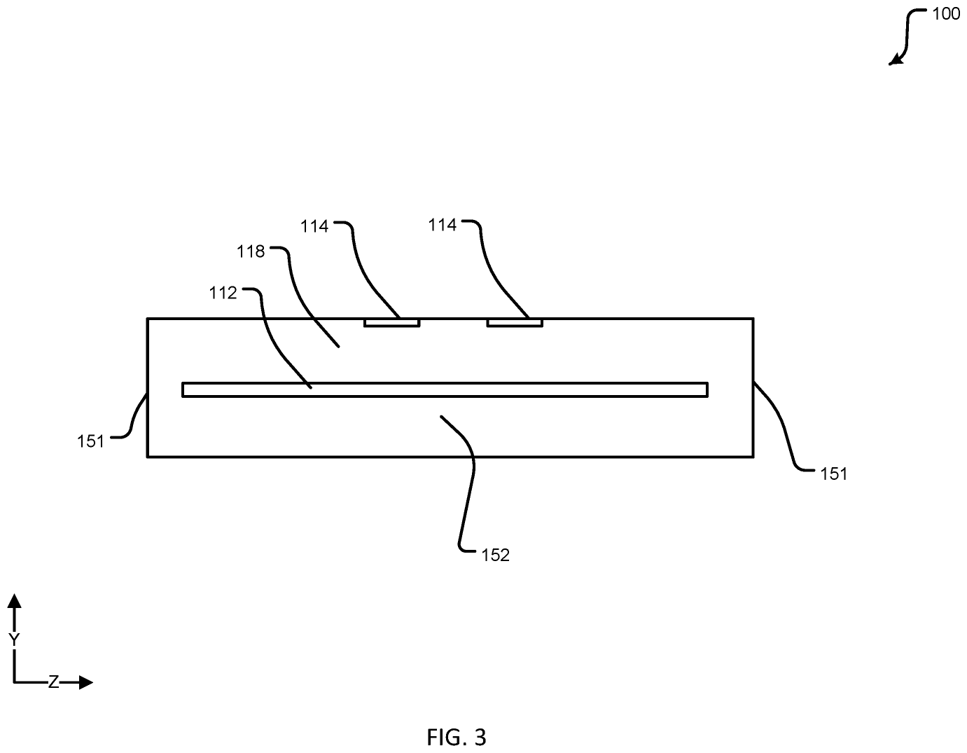

FIG. 3 illustrates a front side view of the power package according to FIG. 1.

The aspects of the power package 100 illustrated in FIGS. 1-3 may optionally be implemented in any other aspects described herein. Moreover, other aspects described herein may optionally be implemented in the power package 100 of FIGS. 1-3.

With reference to FIG. 1, the power package 100 may include an assembly 118, signal contacts 114, power contacts 112, and/or the like. In particular, the assembly 118 may include a top surface 150, first sides 151, and second sides 152. In aspects, the first sides 151 may extend along the X-axis or longitudinal axis between the power contacts 112. In aspects, the second sides 152 may extend along the z-axis or lateral axis. In aspects, the top surface 150 may connect to the first sides 151 and the second sides 152. In aspects, respective ends the first sides 151 and the second sides 152 may be connected.

In aspects, the signal contacts 114 may be configured as at least gate and Kelvin-source signal contacts. In aspects, the signal contacts 114 may be configured to be in and/or on the top surface 150. In other aspects as described herein, the signal contacts 114 may be configured on the top surface, in the top surface, and/or to extend from the top surface 150 along the y-axis or along an axis perpendicular to a plane of the top surface 150.

In aspects, the signal contacts 114 may be arranged between implementations of the second sides 152. In aspects, the signal contacts 114 may be arranged between implementations of the first sides 151. In aspects, the signal contacts 114 may be arranged between implementations of the power contacts 112.

In aspects, the signal contacts 114 may be arranged in a middle section of the top surface 150 between implementations of the second sides 152. In aspects, the signal contacts 114 may be arranged in a middle section of the top surface 150 between implementations of the first sides 151. In aspects, the signal contacts 114 may be arranged in a middle section of the top surface 150 between implementations of the power contacts 112.

In aspects, the signal contacts 114 may be arranged in a middle section of the assembly 118. In aspects, the signal contacts 114 may be arranged in the middle of the assembly 118.

In aspects, the signal contacts 114 may be arranged on a contact lateral axis 102 that extends between the first sides 151 of the power package 100 along the Z-axis or lateral axis. In aspects, the signal contacts 114 may be arranged symmetrically on the contact lateral axis 102. In aspects, the signal contacts 114 may be arranged asymmetrically on the contact lateral axis 102.

In aspects, the contact lateral axis 102 may be parallel to a lateral center axis of the power package 100, may be coincident with the lateral center axis of the power package 100, and/or may be at an angle with the lateral center axis of the power package 100.

In aspects, the signal contacts 114 may be arranged adjacent a longitudinal contact axis 122 of the power package 100 that extends between the second sides 152. In aspects, the signal contacts 114 may be arranged symmetrically adjacent the longitudinal contact axis 122. In aspects, the signal contacts 114 may be arranged asymmetrically adjacent the longitudinal contact axis 122.

In aspects, the longitudinal contact axis 122 may be parallel to a longitudinal center axis of the power package 100, may be coincident with the longitudinal center axis of the power package 100, and/or may be at an angle with the longitudinal center axis of the power package 100.

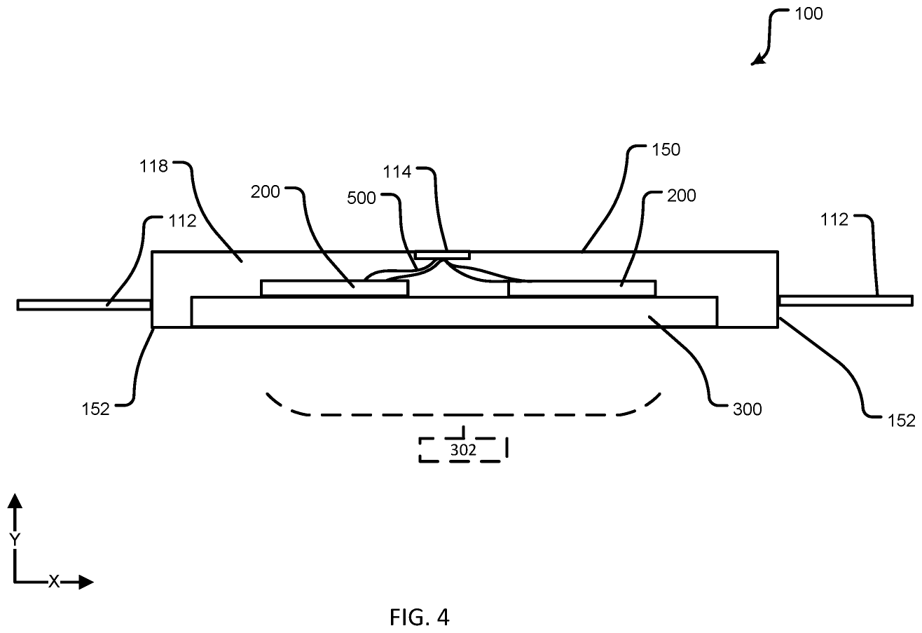

FIG. 4 illustrates a cross-sectional side view of the power package according to FIG. 1.

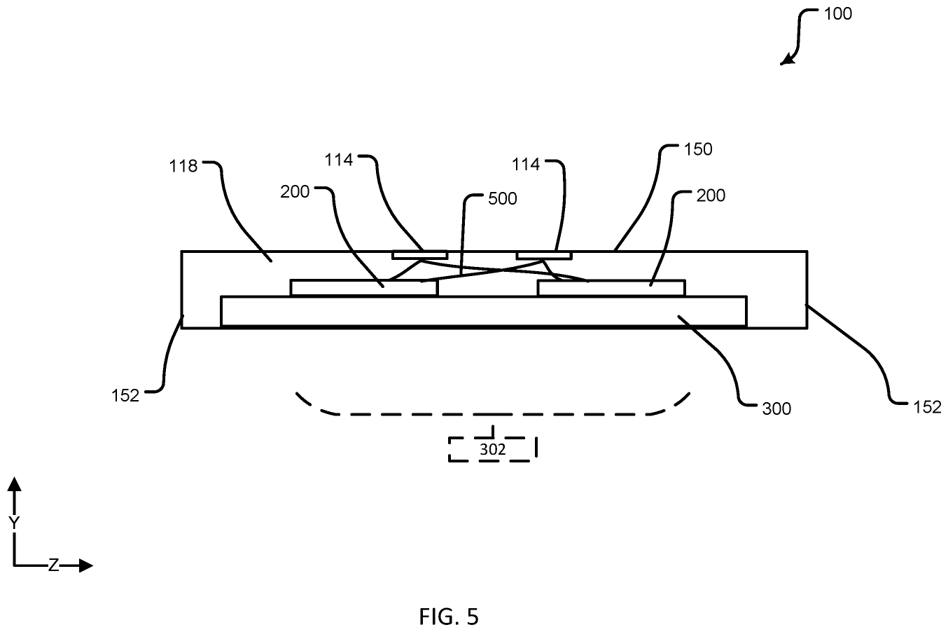

FIG. 5 illustrates a cross-sectional front side view of the power package according to FIG. 1.

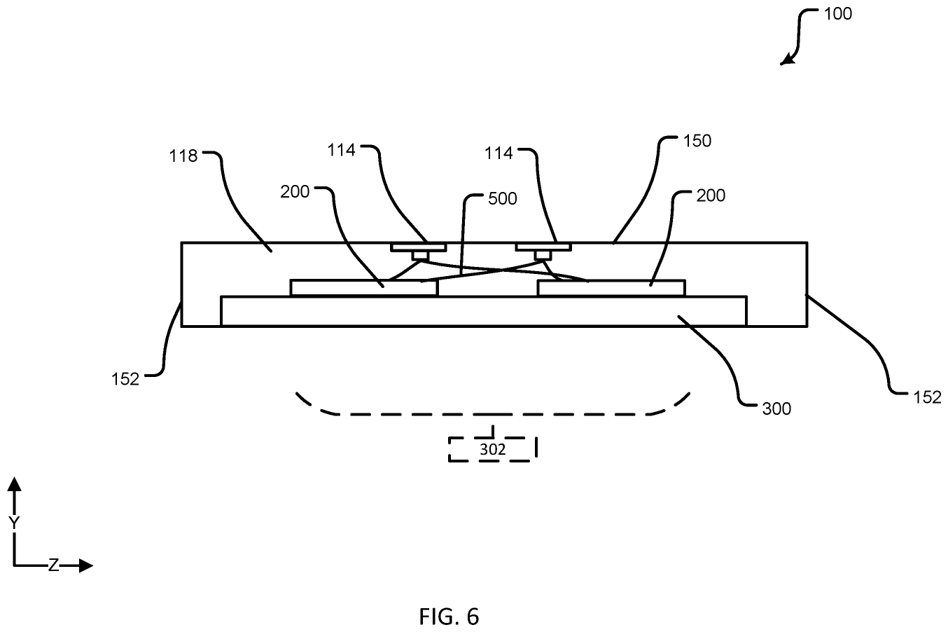

FIG. 6 illustrates another cross-sectional front side view of the power package according to FIG. 1.

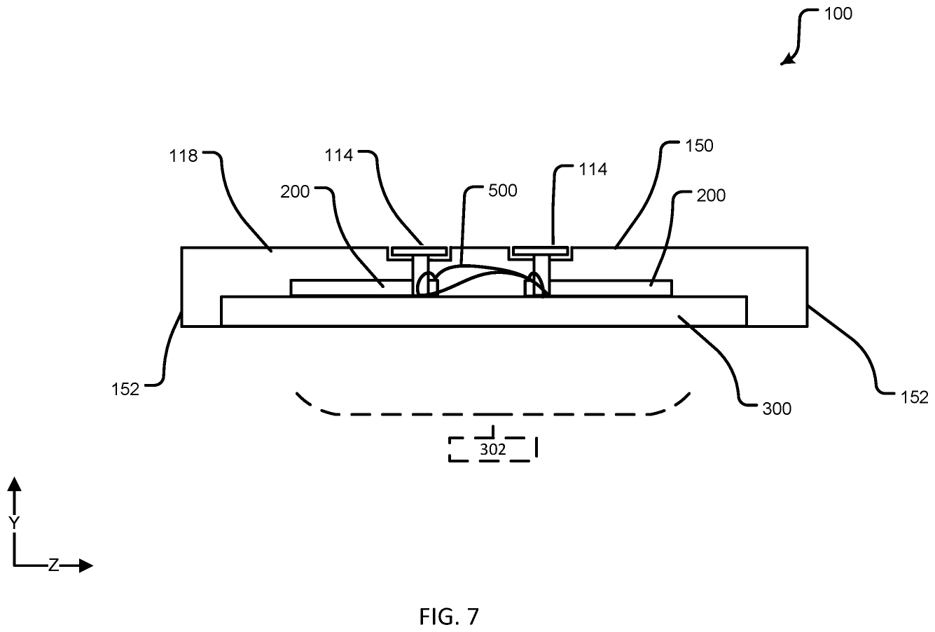

FIG. 7 illustrates another cross-sectional front side view of the power package according to FIG. 1.

The aspects of the power package 100 illustrated in FIGS. 4-7 may optionally be implemented in any other aspects described herein. Moreover, other aspects described herein may optionally be implemented in the power package 100 of FIGS. 4-7.

With reference to FIG. 4, the power package 100 may include one or more power devices 200, a power substrate 300, signal interconnections 500, and/or the like. Further, the signal interconnections 500 may be configured to connect the signal contacts 114 to respective connections on the one or more power devices 200 to provide control signals to the one or more power devices 200.

Note that the figures do not illustrate connections between the power contacts 112 and the one or more power devices 200, the connections between the power contacts 112 and the power substrate 300, and/or the like for ease of illustration. However, it should be recognized that the power package 100 includes connections between the power contacts 112 and the one or more power devices 200, connections between the power contacts 112 and the power substrate 300, and/or the like and these connections may be configured as one or more wire bonds, clips, ribbons, spring contacts, mechanical fasteners, and/or the like.

In aspects, the power package 100 may be configured to arrange the signal contacts 114 in a middle section or middle of the power package 100, so that distance to the one or more power devices 200 will be the same or substantially the same. In this regard, the power package 100 may be configured such that implementations of the one or more power devices 200 may have the same or nearly same gate-loop inductance. Accordingly, the power package 100 may be configured such that an overall gate-loop inductance of the power package 100 may be lower. Moreover, a configuration of the signal contacts 114, the signal interconnections 500, and the power package 100 may be configured such that half of the drain-source current may flow on one side of the power package 100 and another half on the other side of the power package 100. Consequently, magnetic fields in the middle of the power package 100 may cancel each other.

Further, the signal contacts 114 may be arranged directly above the power substrate 300. In aspects, the signal contacts 114 may be arranged directly above the power substrate 300 along the y-axis or vertical axis (vertical relative to the orientation of the power package 100 as illustrated). In aspects, the signal contacts 114 may be arranged directly above the power substrate 300 along an axis perpendicular to a surface of the power substrate 300 supporting the one or more power devices 200.

In aspects, the power substrate 300 may include a die attach region 302 where the one or more power devices 200 are arranged on a surface of the power substrate 300. In this regard, the die attach region 302 may be defined as the area on the power substrate 300 where all of the one or more power devices 200 are arranged as illustrated in FIG. 4 and FIG. 5.

Further, the signal contacts 114 may be arranged directly above the die attach region 302. In aspects, the signal contacts 114 may be arranged directly above the die attach region 302 along the y-axis or vertical axis (vertical relative to the orientation of the power package 100 as illustrated). In aspects, the signal contacts 114 may be arranged directly above the die attach region 302 along an axis perpendicular to a surface of the power substrate 300 supporting the one or more power devices 200.

In aspects, the signal interconnection 500 may be configured as a topside electrical connection of signal pads of the one or more power devices 200 to the signal contacts 114 of the power package 100. In aspects, the signal interconnection 500 may be configured as one or more signal wire bonds, clips, ribbons, and/or the like.

In aspects, the signal interconnections 500 may each have a length from the signal contacts 114 to the one or more power devices 200. In aspects, the signal interconnections 500 may each have a similar length from the signal contacts 114 to the one or more power devices 200, where a similar length is within 0%-2%, 2%-4%, 4%-6%, 6%-8%, 8%-10%, 10%-14%, or 14%-20% in length. In aspects, the signal interconnections 500 may each have a same length from the signal contacts 114 to the one or more power devices 200.

In aspects, the signal interconnections 500 configured as gate interconnections may each have a length from the signal contacts 114 to the one or more power devices 200. In aspects, the signal interconnections 500 configured as gate interconnections may each have a similar length from the signal contacts 114 to the one or more power devices 200, where a similar length is within 0%-2%, 2%-4%, 4%-6%, 6%-8%, 8%-10%, 10%-14%, or 14%-20% in length. In aspects, the signal interconnections 500 configured as gate interconnections may each have a same length from the signal contacts 114 to the one or more power devices 200.

In aspects, the signal interconnections 500 configured as kelvin source interconnections may each have a length from the signal contacts 114 to the one or more power devices 200. In aspects, the signal interconnections 500 configured as kelvin source interconnections may each have a similar length from the signal contacts 114 to the one or more power devices 200, where a similar length is within 0%-2%, 2%-4%, 4%-6%, 6%-8%, 8%-10%, 10%-14%, or 14%-20% in length. In aspects, the signal interconnections 500 configured as kelvin source interconnections may each have a same length from the signal contacts 114 to the one or more power devices 200.

In aspects, the power package 100 has an overall gate-loop inductance that is generated based on a construction and configuration of the signal contacts 114 and/or the signal interconnections 500 may each have. In aspects, the signal contacts 114 and/or the signal interconnections 500 may be constructed and configured to have a similar overall gate-loop inductance, where a similar overall gate-loop inductance is within 0%-2%, 2%-4%, or 4%-6%, 6%-8%, 8%-10%, or 10%-14%, in inductance. In aspects, the signal contacts 114 and/or the signal interconnections 500 may be constructed and configured to have a similar overall gate-loop inductance, where a similar overall gate-loop inductance is within 2 nH, 3 nH, 4 nH, 6 nH, 8 nH, or 10 nH. In aspects, the signal contacts 114 and/or the signal interconnections 500 may be constructed and configured to have a have a same gate-loop inductance.

In aspects, the electrical and mechanical connections between the signal contacts 114 and the signal interconnections 500 and the signal interconnections 500 and the one or more power devices 200 may include welded portions, welding, soldered portions, soldering, conductive epoxy, and/or the like.

In aspects, the power package 100 may be configured with a contact joint. The contact joint may be configured as a joint to the power substrate 300 inside the assembly 118 of the power package 100. In aspects, the signal contacts 114 may be over-molded as illustrated in FIG. 6 or the signal contacts 114 can be placed in holes or blind holes and/or openings of the assembly 118 of the power package 100 as illustrated in FIG. 7.

With further reference to FIG. 4 and FIG. 5, the signal contacts 114 may be arranged and attached to the top surface 150 of the assembly 118. In particular, a bottom surface of the signal contacts 114 may be arranged and attached to the top surface 150 of the assembly 118.

With reference to FIG. 6, the signal contacts 114 may be at least partially within the assembly 118. In particular, a bottom surface of the signal contacts 114 may be arranged and attached within the assembly 118. In this regard, the FIG. 6 implementation of the signal contacts 114 may be molded into the assembly 118. In aspects, a bottom surface of the signal contacts 114 may be molded into the assembly 118.

With reference to FIG. 7, the assembly 118 may be configured with apertures for the signal contacts 114. In this regard, the power package 100 may be configured such that the signal contacts 114 may be at least partially arranged within apertures in the assembly 118. In this regard, the apertures may be formed in the assembly 118 and the signal contacts 114 secured within the apertures.

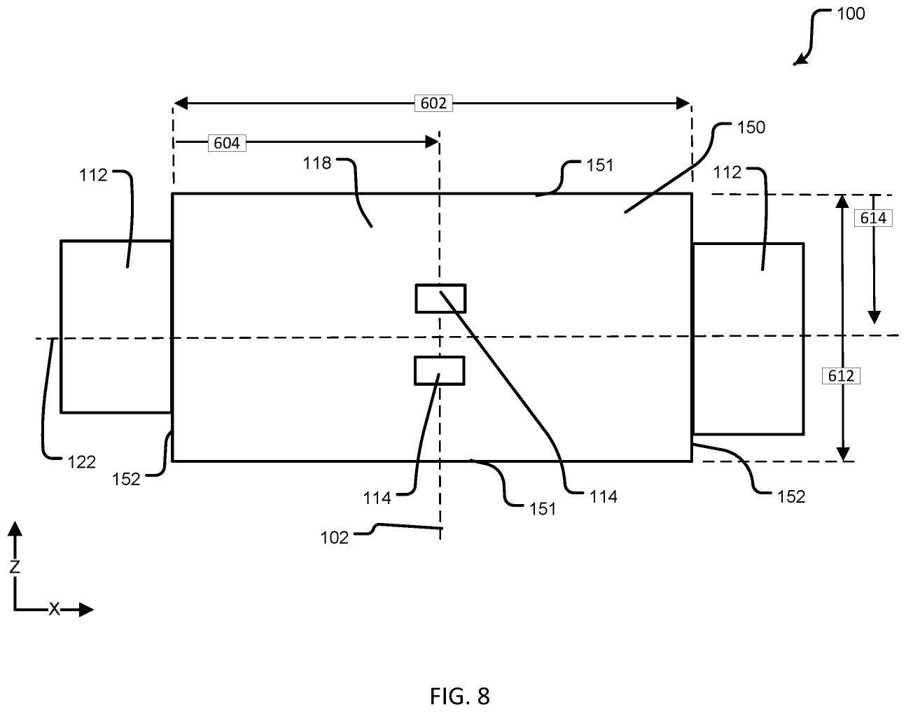

FIG. 8 illustrates a top view of the power package according to FIG. 1.

The aspects of the power package 100 illustrated in FIG. 8 may optionally be implemented in any other aspects described herein. Moreover, other aspects described herein may optionally be implemented in the power package 100 of FIG. 8.

With reference to FIG. 8, the signal contacts 114 may be arranged on the top surface 150 of the power package 100 on the contact lateral axis 102. In this regard, the contact lateral axis 102 may be arranged anywhere on the top surface 150 of the power package 100.

Additionally, the signal contacts 114 may be arranged symmetrically adjacent the longitudinal contact axis 122. In this regard, the longitudinal contact axis 122 may be arranged anywhere on the top surface 150 of the power package 100.

Further, the first sides 151 may have a longitudinal length 602 that extends between the second sides 152 as illustrated in FIG. 8; and the second sides 152 may have a lateral length 612 that extends between the first sides 151 as illustrated in FIG. 8.

Further, the contact lateral axis 102 may include a longitudinal position along the X-axis that may be defined by the longitudinal length 602 of the first sides 151. In this regard, the contact lateral axis 102 may be located a length 604 from one of the second sides 152. In aspects, the length 604 may be 10%-20%, 20%-30%, 30%-40%, 40%-50%, or 50%-60% of the length of the longitudinal length 602.

Further, the longitudinal contact axis 122 may include a lateral position along the Z-axis that may be defined by the lateral length 612 of the second sides 152. In this regard, the longitudinal contact axis 122 may be located a length 614 from one of the first sides 151. In aspects, the length 614 may be 10%-20%, 20%-30%, 30%-40%, 40%-50%, or 50%-60% of the length of the lateral length 612.

Additionally, aspects of the power package 100 may further implement the signal contacts 114 with a spacing between respective implementations of the signal contacts 114. In this regard and with reference to FIG. 8, a spacing between respective implementations of the signal contacts 114 along the contact lateral axis 102 and/or the z-axis.

In aspects, the spacing between respective implementations of the signal contacts 114 in certain implementations of the power package 100 may be 1 mm-10 mm, 1 mm-2 mm, 2 mm-3 mm, 3 mm-4 mm, 4 mm-5 mm, 5 mm-6 mm, 6 mm-7 mm, 7 mm-8 mm, 8 mm-9 mm, or 9 mm-10 mm. In aspects, the spacing between respective implementations of the signal contacts 114 in certain implementations of the power package 100 may be less than 2 mm, less than 3 mm, less than 4, less than 5 mm, less than 6 mm, less than 7 mm, less than 8 mm, less than 9 mm, or less than 10 mm.

In aspects, the spacing between respective implementations of the signal contacts 114 in certain implementations of the power package 100 may be 1%-25%, 1%-5%, 5%-10%, 10%-15%, 15%-20%, or 20%-25% of the lateral length 612. In aspects, the spacing between respective implementations of the signal contacts 114 in certain implementations of the power package 100 may be less than 5%, less than 10%, less than 15%, less than 20%, or less than 25% of the lateral length 612. In aspects, the spacing between respective implementations of the signal contacts 114 may be as close as possible.

In aspects, the signal contacts 114 are illustrated with a pad configuration that may be implemented with a press-fit connection and/or the like. However, the signal contacts 114 may be implemented using any type of connector technology and/or configuration including one or more of pin connector configurations, blade connector configurations, plug configurations, plug-and-socket connection configurations, plug configurations, socket configurations, male connection configurations, pin contact configurations, female socket configurations, pogo pin configurations, spring loaded connector configurations, locking connector configurations, keying connector configurations, and/or the like.

In aspects, the power package 100 may be configured such that there may be any number of the signal contacts 114 including two of the signal contacts 114, three of the signal contacts 114, four of the signal contacts 114 or more. Additional implementations of the signal contacts 114 may be implemented in the power package 100 for additional functions of the power package 100.

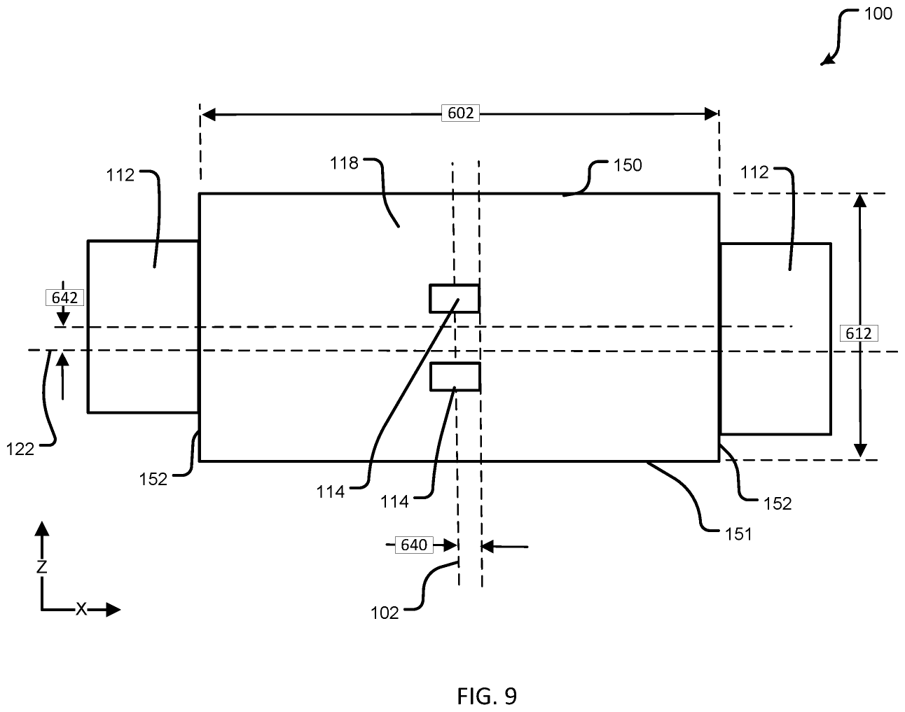

FIG. 9 illustrates a top view of the power package according to FIG. 1.

The aspects of the power package 100 illustrated in FIG. 9 may optionally be implemented in any other aspects described herein. Moreover, other aspects described herein may optionally be implemented in the power package 100 of FIG. 9.

With reference to FIG. 9, the contact lateral axis 102 may be offset from a center lateral axis of the power package 100 by a longitudinal offset distance 640. In aspects, the longitudinal offset distance 640 may be 0%-5%, 10%-15%, 15%-20%, or 20%-25% of the longitudinal length 602. In aspects, the longitudinal offset distance 640 may be up to 5%, up to 10%, up to 15%, up to 20%, or up to 25% of the longitudinal length 602.

With further reference to FIG. 9, the longitudinal contact axis 122 may be offset from a center longitudinal axis of the power package 100 by a lateral offset distance 642. In aspects, the lateral offset distance 642 may be 0%-5%, 10%-15%, 15%-20%, or 20%-25% of the lateral length 612. In aspects, the lateral offset distance 642 may be up to 5%, up to 10%, up to 15%, up to 20%, or up to 25% of the lateral length 612.

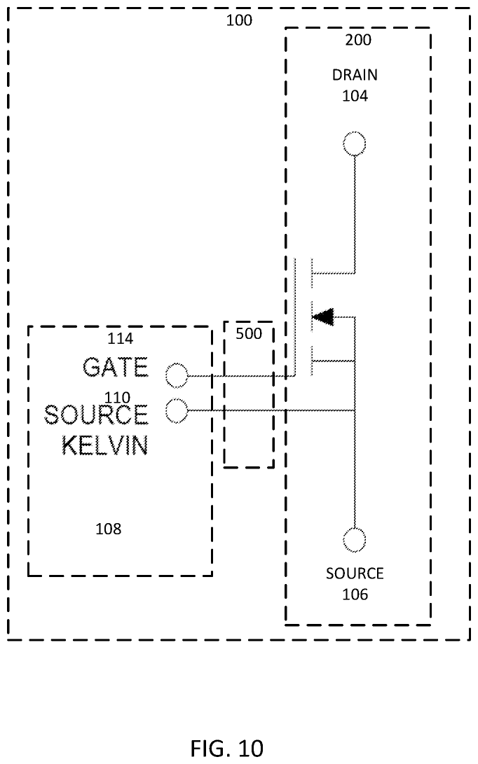

FIG. 10 illustrates a partial schematic topology of the power package according to aspects of the disclosure.

In particular, FIG. 10 illustrates a schematic topology of the power package 100 according to aspects of the disclosure. More specifically, FIG. 10 illustrates a single nonlimiting implementation of the one or more power devices 200 for ease of illustration only. Accordingly, aspects of the power package 100 having multiple implementations of the one or more power devices 200 would be implemented similarly.

In aspects, the power package 100 may implement the signal contacts 114 with at least a source Kelvin terminal 108 and a gate terminal 110. Further, the power package 100 may implement the one or more power devices 200 with a drain terminal 104 and a source terminal 106. Additionally, FIG. 10 schematically illustrates the arrangement of the signal interconnections 500 between the signal contacts 114 and the one or more power devices 200.

It should be further noted that a physical implementation internally of the source Kelvin terminal 108 of the power package 100 may include a number of configurations. In aspects, the source Kelvin terminal 108 of the power package 100 may be implemented and configured as a true source kelvin, which configuration of the source Kelvin terminal 108 may be implemented with no overlapping path of power and signal loops.

Additionally, it should be appreciated that the implementation of the power package 100 illustrated in FIG. 10 are for a MOSFET implementation of the power package 100. In other aspects, the power package 100 may be implemented with other terminal configurations and other power device types, such as IGBT, JFET, and/or the like power device types. In this regard, the connections in these implementations of the power package 100 may be similar; however, the terminal names and circuit symbols for these implementations of the power package 100 would be specific to those power device types.

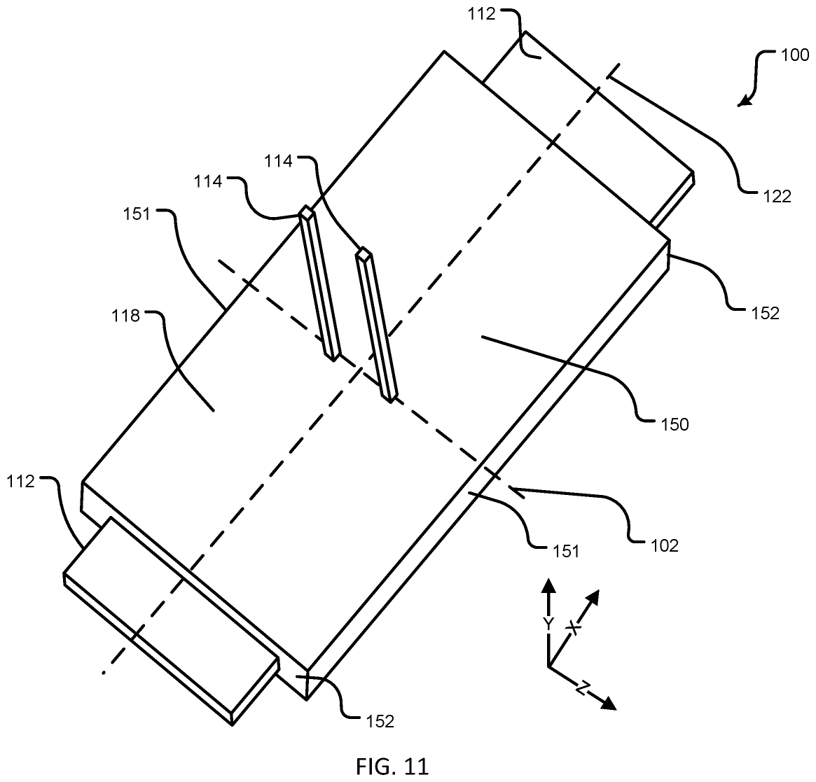

FIG. 11 illustrates a top side perspective view of a power package according to aspects of the disclosure.

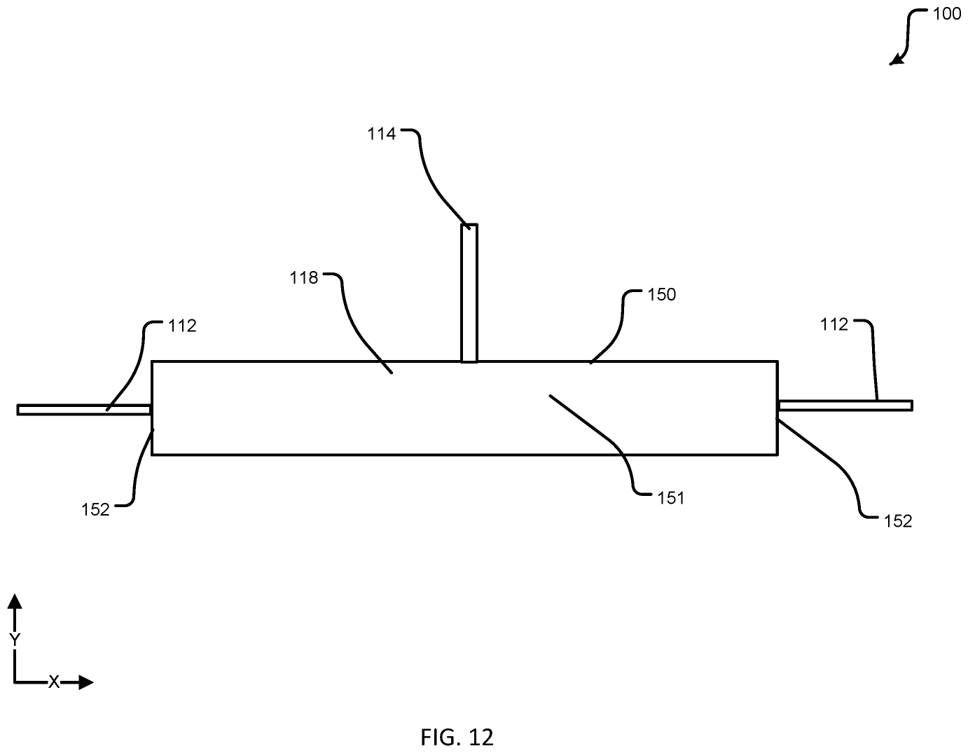

FIG. 12 illustrates a side view of the power package according to FIG. 11.

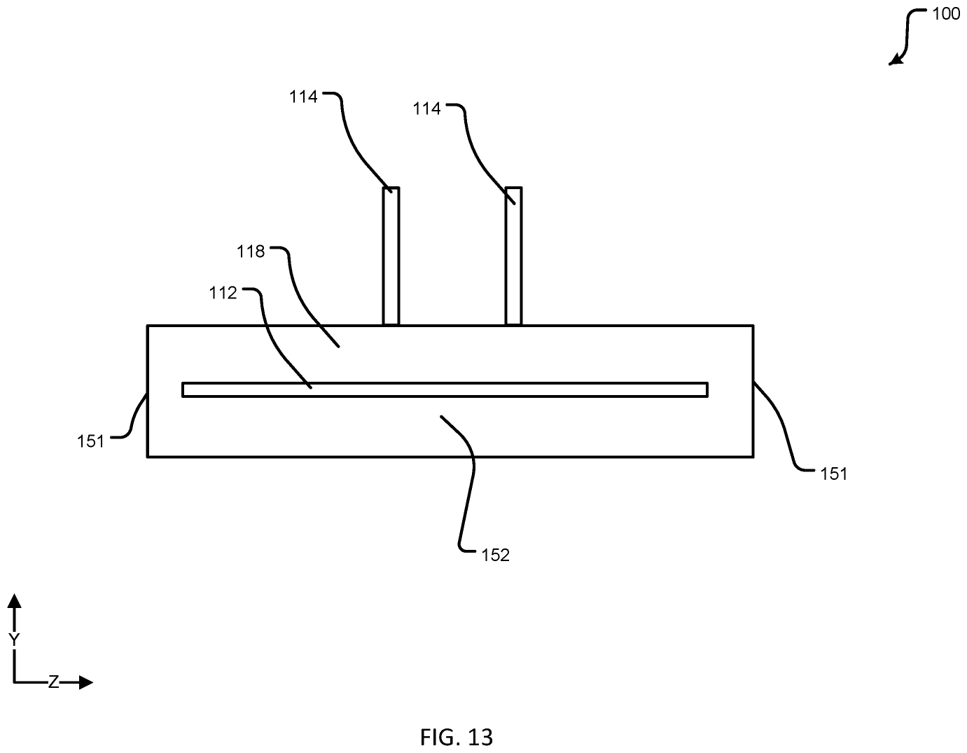

FIG. 13 illustrates a front side view of the power package according to FIG. 11.

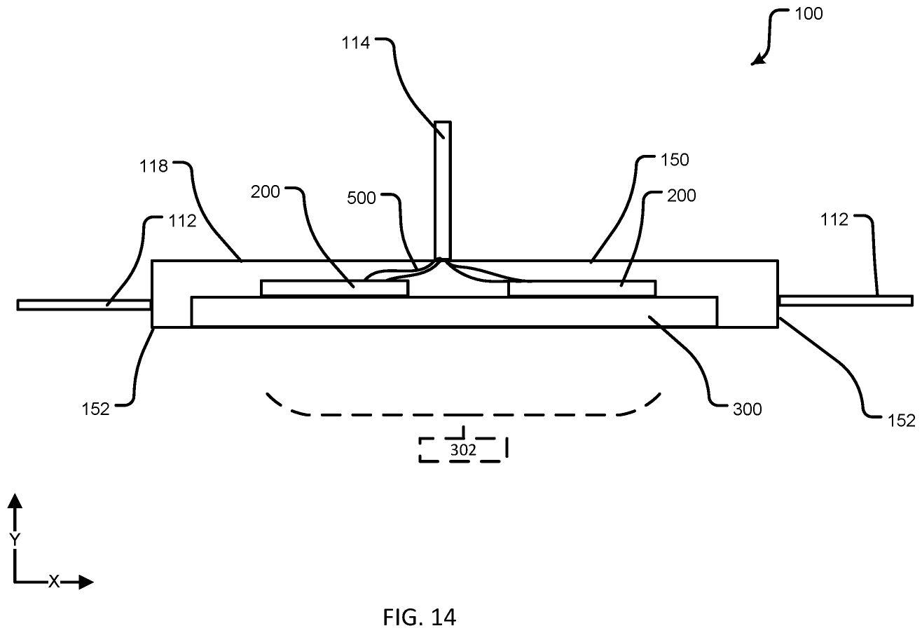

FIG. 14 illustrates a cross-sectional side view of the power package according to FIG. 11.

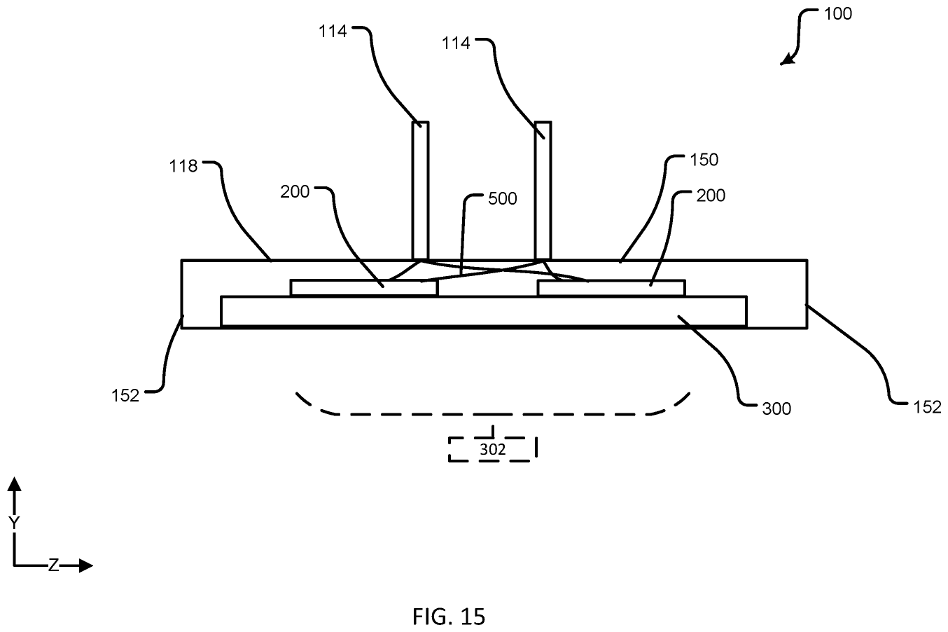

FIG. 15 illustrates a cross-sectional front side view of the power package according to FIG. 11.

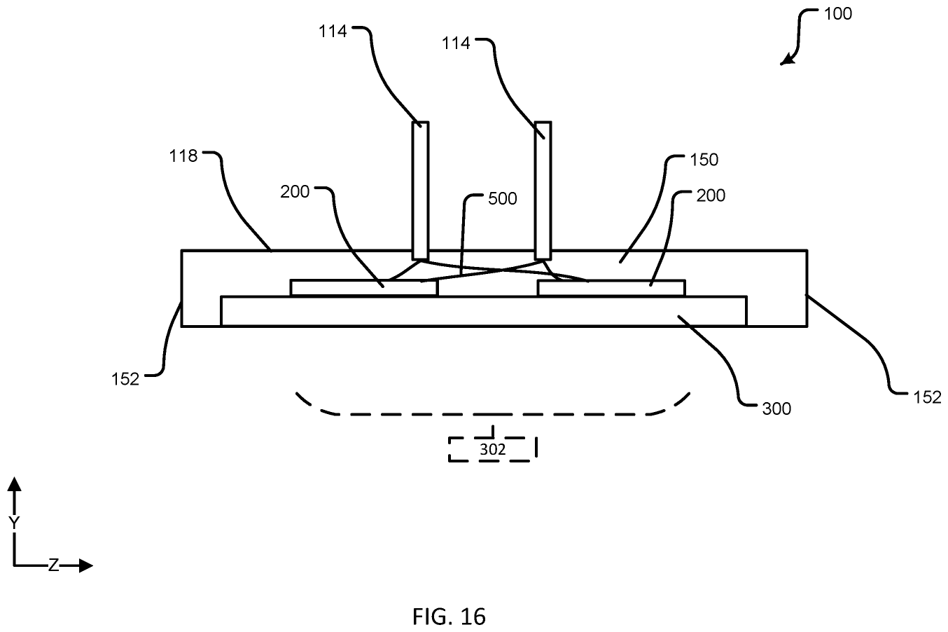

FIG. 16 illustrates another cross-sectional front side view of the power package according to FIG. 11.

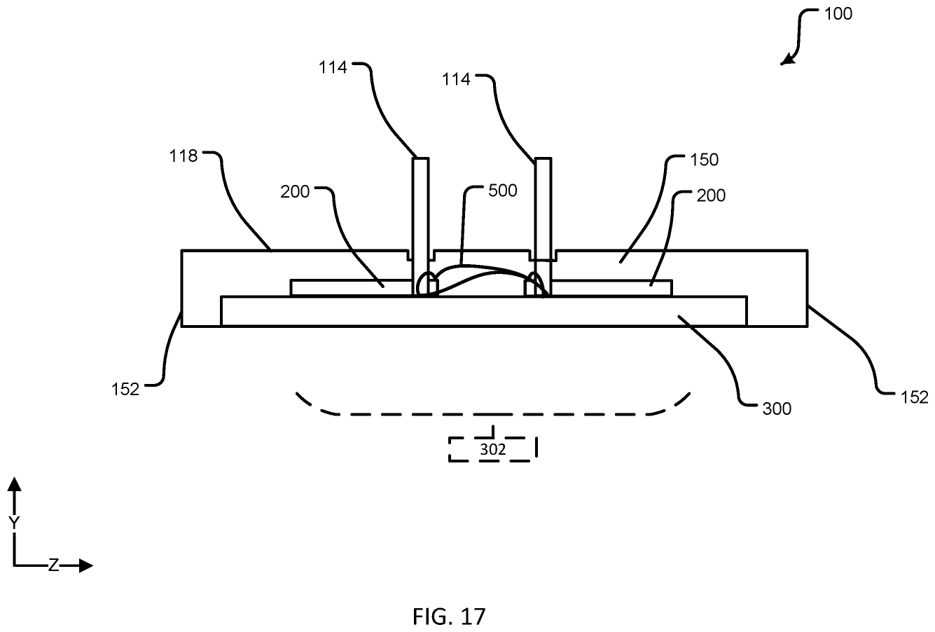

FIG. 17 illustrates another cross-sectional front side view of the power package according to FIG. 11.

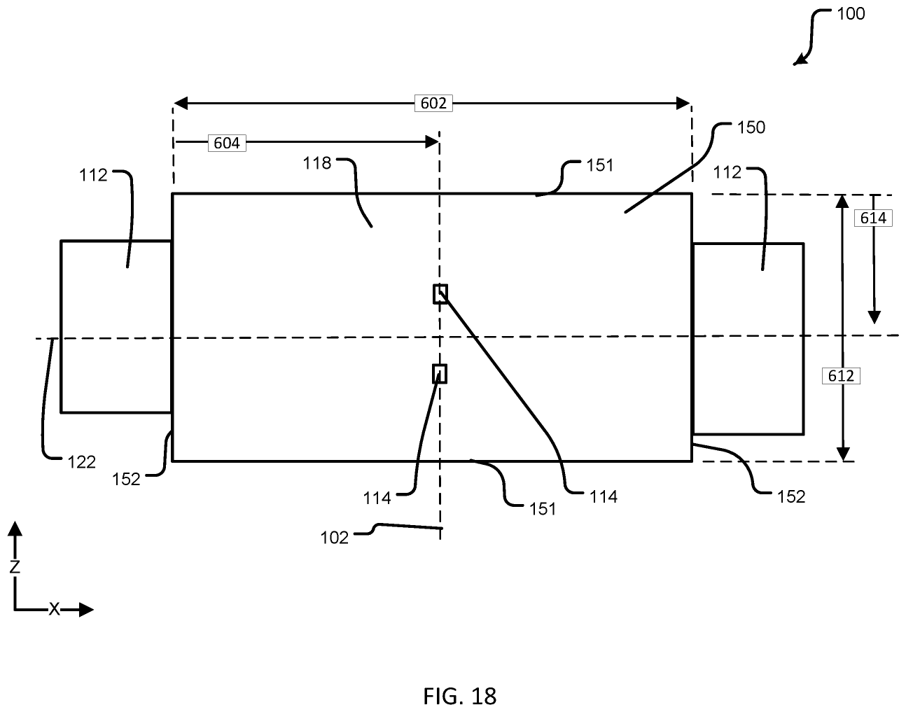

FIG. 18 illustrates a top view of the power package according to FIG. 11.

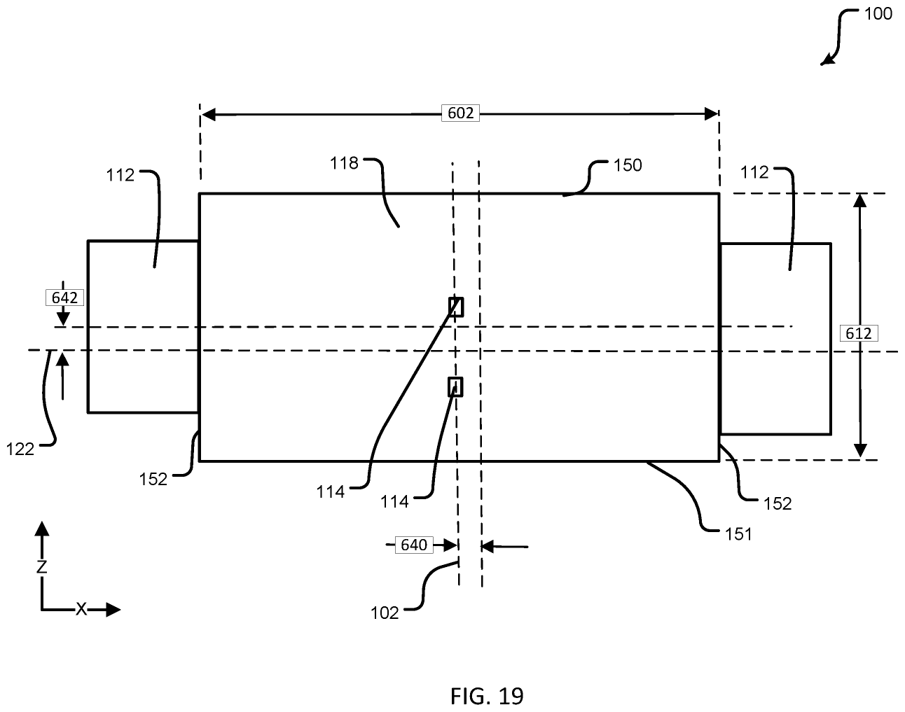

FIG. 19 illustrates a top view of the power package according to FIG. 11.

The aspects of the power package 100 illustrated in FIGS. 11-19 may optionally be implemented in any other aspects described herein. Moreover, other aspects described herein may optionally be implemented in the power package 100 of FIGS. 11-19.

With reference to FIG. 11, the power package 100 may include the various features of the power package 100 as previously described herein. Further, the FIG. 11 implementation of the power package 100 illustrates another arrangement of the signal contacts 114. In aspects, the signal contacts 114 may be configured to extend from the top surface 150 along the y-axis or along an axis perpendicular to a plane of the top surface 150.

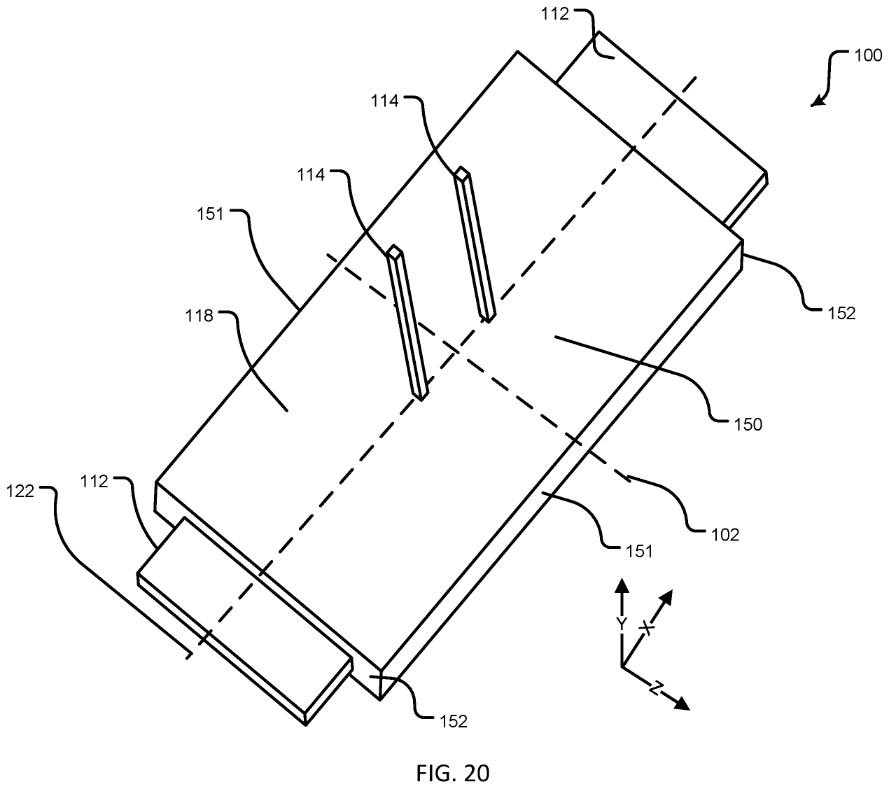

FIG. 20 illustrates a top side perspective view of a power package according to aspects of the disclosure.

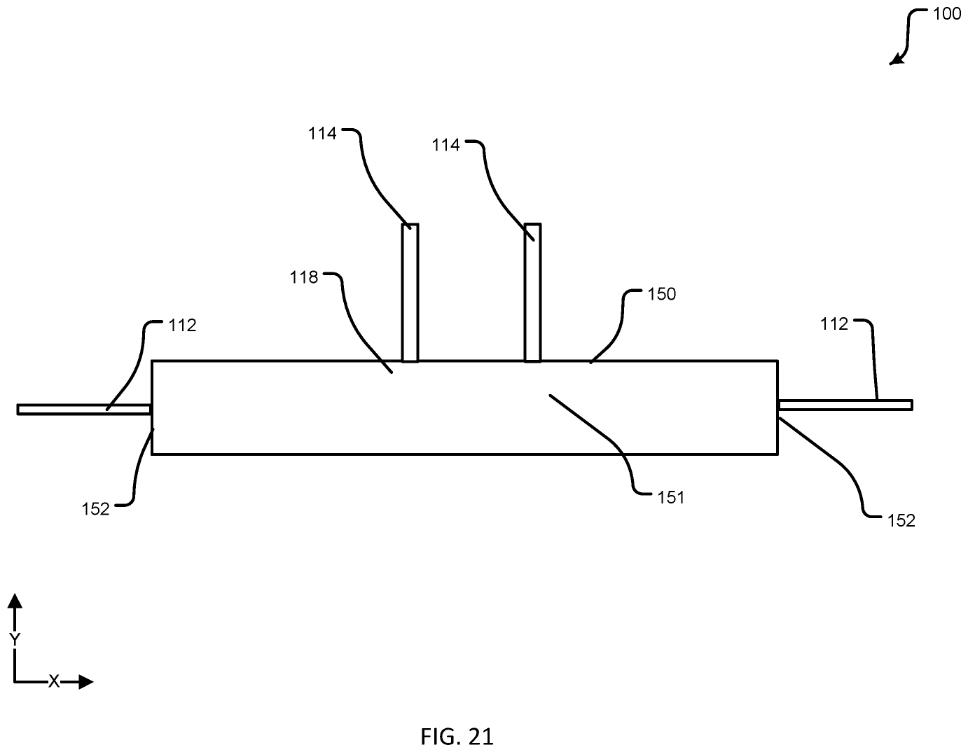

FIG. 21 illustrates a side view of the power package according to FIG. 20.

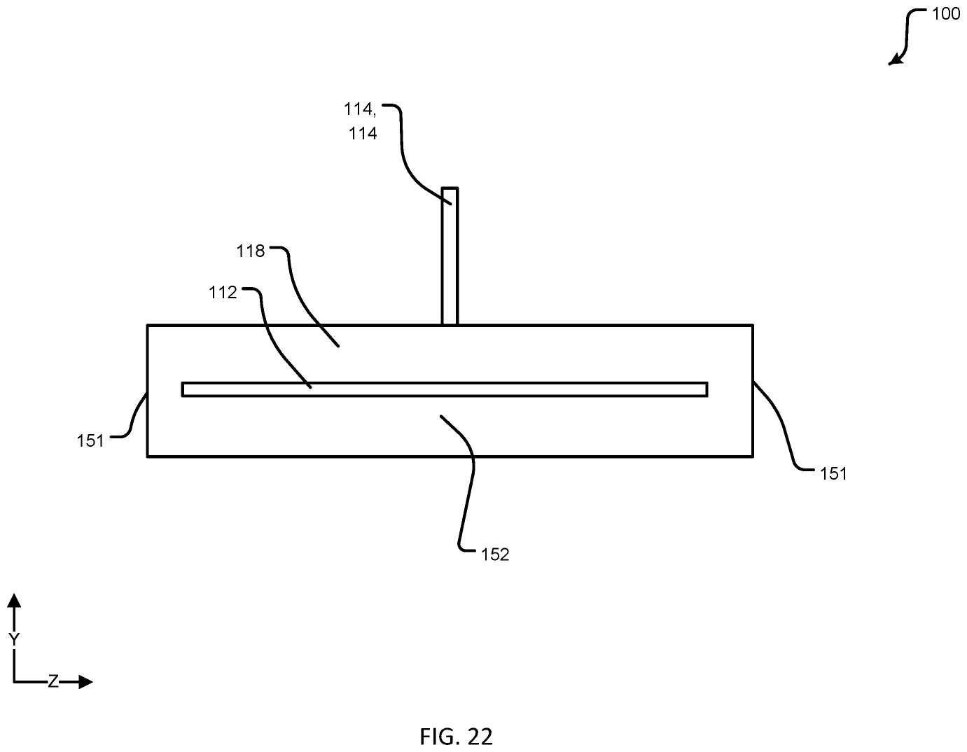

FIG. 22 illustrates a front side view of the power package according to FIG. 20.

The aspects of the power package 100 illustrated in FIGS. 20-22 may optionally be implemented in any other aspects described herein. Moreover, other aspects described herein may optionally be implemented in the power package 100 of FIGS. 20-22.

With reference to FIG. 20, the power package 100 may include the various features of the power package 100 as previously described herein. Further, the FIG. 20 implementation of the power package 100 illustrates another arrangement of the signal contacts 114.

In aspects, the signal contacts 114 may be arranged on the longitudinal contact axis 122. In aspects, the signal contacts 114 may be arranged symmetrically on the longitudinal contact axis 122. In aspects, the signal contacts 114 may be arranged asymmetrically on the longitudinal contact axis 122.

In aspects, the signal contacts 114 may be arranged adjacent the contact lateral axis 102. In aspects, the signal contacts 114 may be arranged symmetrically adjacent the contact lateral axis 102. In aspects, the signal contacts 114 may be arranged asymmetrically adjacent the contact lateral axis 102.

Additionally, the contact lateral axis 102 may be located the length 604 (illustrated in FIG. 8) from one of the second sides 152 as previously disclosed herein; and/or the longitudinal contact axis 122 may be located the length 614 (illustrated in FIG. 8) from one of the first sides 151 as previously disclosed herein.

Additionally, the contact lateral axis 102 may be offset from a center lateral axis of the power package 100 by the longitudinal offset distance 640 (illustrated in FIG. 9) as previously disclosed herein. Moreover, the longitudinal contact axis 122 may be offset from a center longitudinal axis of the power package 100 by the lateral offset distance 642 (illustrated in FIG. 9) as previously disclosed herein.

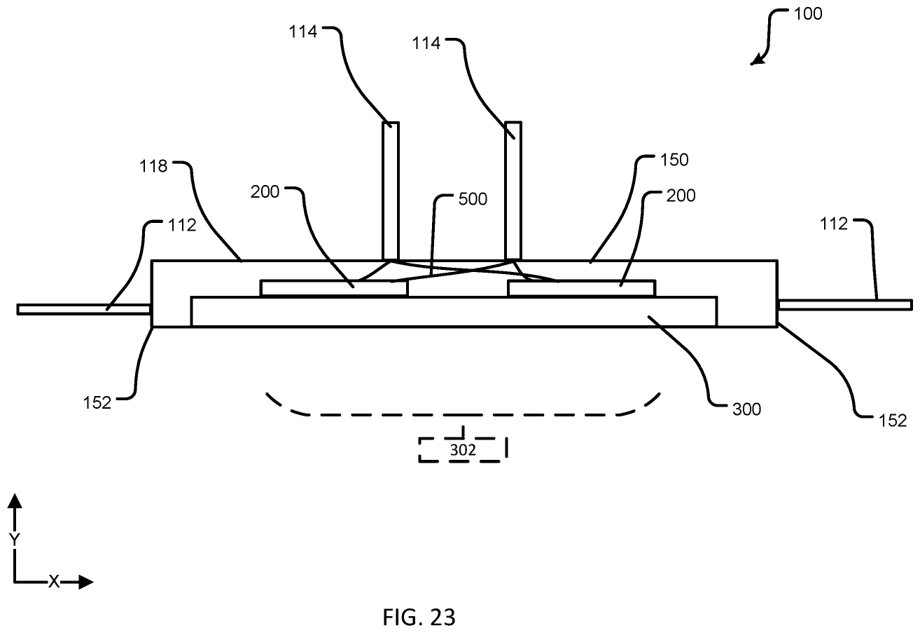

FIG. 23 illustrates a cross-sectional side view of the power package according to FIG. 20.

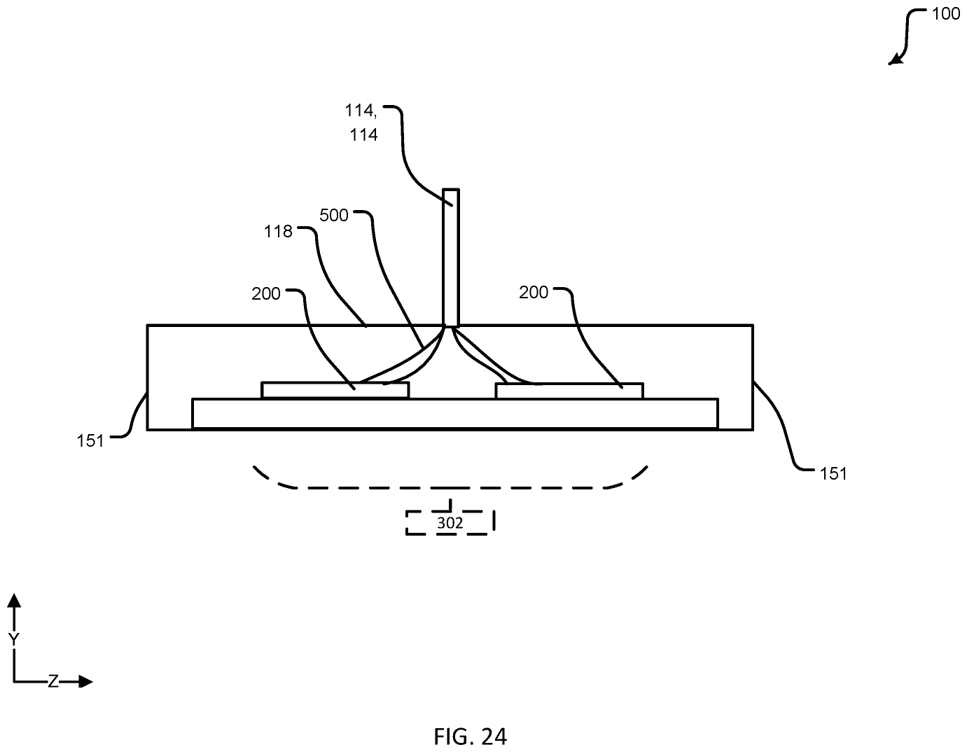

FIG. 24 illustrates a cross-sectional front side view of the power package according to FIG. 20.

The aspects of the power package 100 illustrated in FIGS. 23 and 24 optionally be implemented in any other aspects described herein. Moreover, other aspects described herein may optionally be implemented in the power package 100 of FIGS. 23 and 24.

Further, the signal contacts 114 may be arranged directly above the power substrate 300. In aspects, the signal contacts 114 may be arranged directly above the power substrate 300 along the y-axis or vertical axis (vertical relative to the orientation of the power package 100 as illustrated). In aspects, the signal contacts 114 may be arranged directly above the power substrate 300 along an axis perpendicular to a surface of the power substrate 300 supporting the one or more power devices 200.

Further, the signal contacts 114 may be arranged directly above the die attach region 302. In aspects, the signal contacts 114 may be arranged directly above the die attach region 302 along the y-axis or vertical axis (vertical relative to the orientation of the power package 100 as illustrated). In aspects, the signal contacts 114 may be arranged directly above the die attach region 302 along an axis perpendicular to a surface of the power substrate 300 supporting the one or more power devices 200.

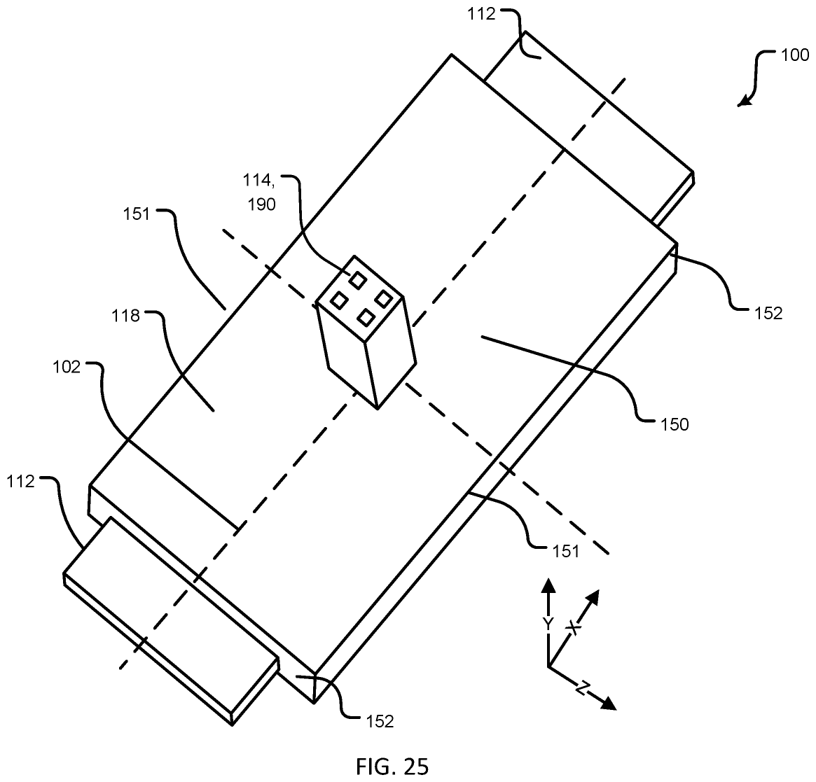

FIG. 25 illustrates a top side perspective view of a power package according to aspects of the disclosure.

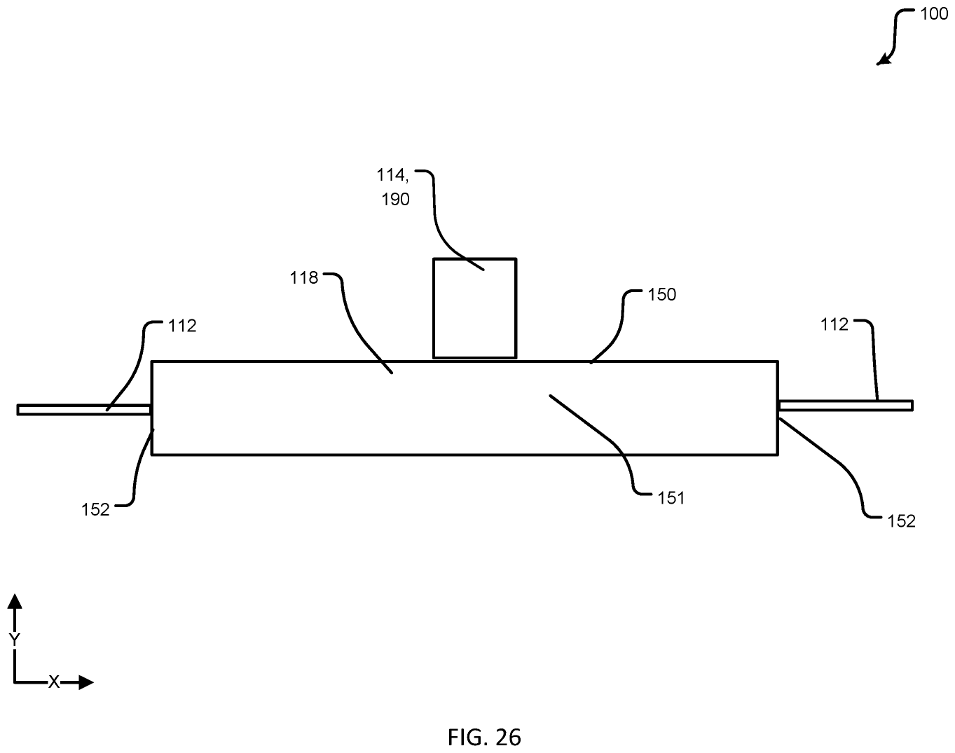

FIG. 26 illustrates a side view of the power package according to FIG. 25.

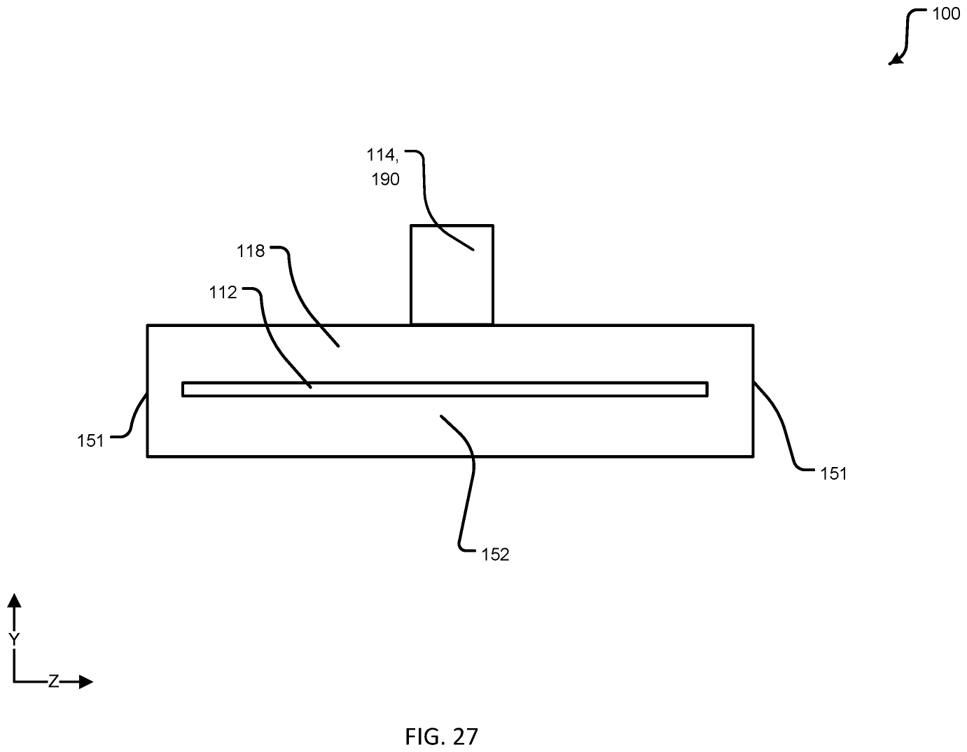

FIG. 27 illustrates a front side view of the power package according to FIG. 25.

The aspects of the power package 100 illustrated in FIGS. 25-27 may optionally be implemented in any other aspects described herein. Moreover, other aspects described herein may optionally be implemented in the power package 100 of FIGS. 25-27.

With reference to FIG. 25, the power package 100 may include the various features of the power package 100 as previously described herein. Further, the FIG. 25 implementation of the power package 100 illustrates another configuration of the signal contacts 114 implemented as a receptacle 190.

In aspects, the receptacle 190 may be implemented with an appearance similar to a standard surface mount device (SMD) header. In aspects, the receptacle 190 may have ends compatible to press-fit technology or be any other type of pins. In aspects, the receptacle 190 may be configured as a receptacle, may be configured as a female type connection header, and/or may be implemented as control connectors. In other aspects, the receptacle 190 may be implemented using any type of connector technology and/or configuration including one or more of pin connector configurations, blade connector configurations, plug configurations, plug-and-socket connection configurations, plug configurations, socket configurations, male connection configurations, pin contact configurations, female socket configurations, pogo pin configurations, spring loaded connector configurations, locking connector configurations, keying connector configurations, and/or the like.

In aspects, the receptacle 190 may be arranged on the longitudinal contact axis 122 and/or on the contact lateral axis 102.

Additionally, the contact lateral axis 102 may be located the length 604 (illustrated in FIG. 8) from one of the second sides 152 as previously disclosed herein; and/or the longitudinal contact axis 122 may be located the length 614 (illustrated in FIG. 8) from one of the first sides 151 as previously disclosed herein.

Additionally, the contact lateral axis 102 may be offset from a center lateral axis of the power package 100 by the longitudinal offset distance 640 (illustrated in FIG. 9) as previously disclosed herein. Moreover, the longitudinal contact axis 122 may be offset from a center longitudinal axis of the power package 100 by the lateral offset distance 642 (illustrated in FIG. 9) as previously disclosed herein.

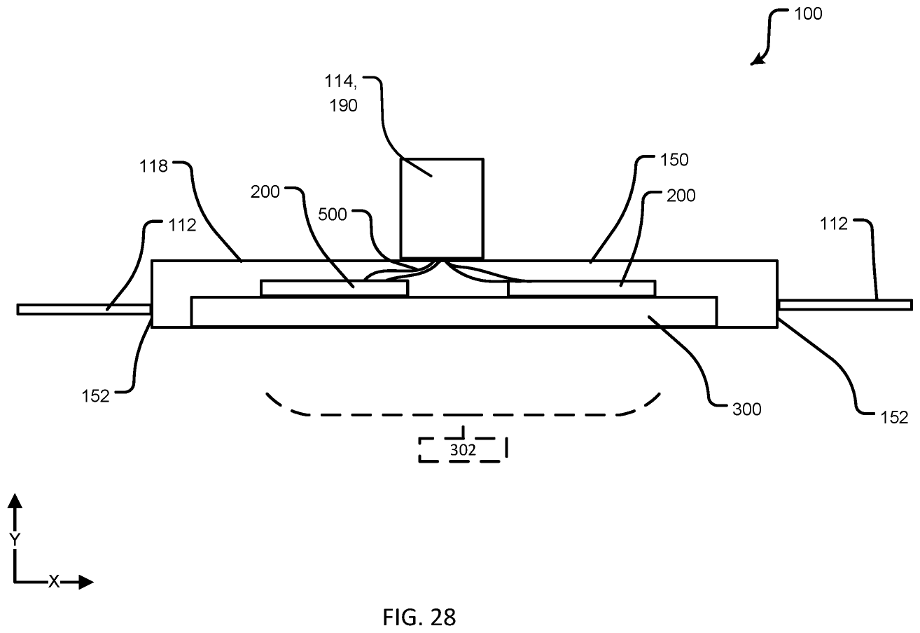

FIG. 28 illustrates a cross-sectional side view of the power package according to FIG. 25.

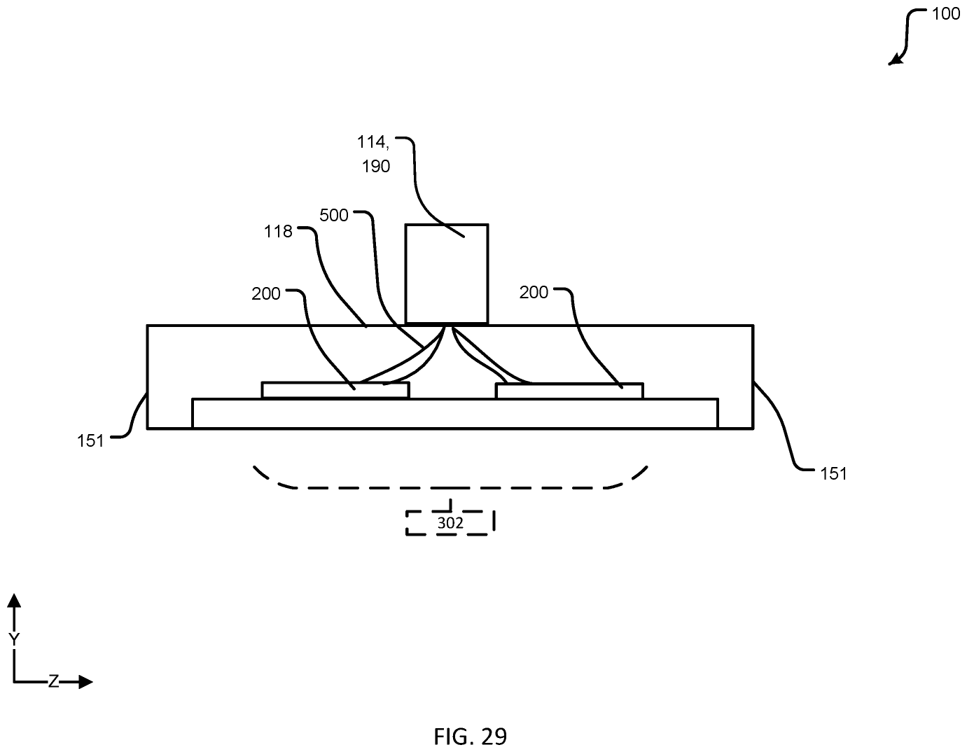

FIG. 29 illustrates a cross-sectional front side view of the power package according to FIG. 25.

The aspects of the power package 100 illustrated in FIGS. 28 and 29 may optionally be implemented in any other aspects described herein. Moreover, other aspects described herein may optionally be implemented in the power package 100 of FIGS. 28 and 29.

Further, the receptacle 190 may be arranged directly above the power substrate 300. In aspects, the receptacle 190 may be arranged directly above the power substrate 300 along the y-axis or vertical axis (vertical relative to the orientation of the power package 100 as illustrated). In aspects, the receptacle 190 may be arranged directly above the power substrate 300 along an axis perpendicular to a surface of the power substrate 300 supporting the one or more power devices 200.

Further, the receptacle 190 may be arranged directly above the die attach region 302. In aspects, the receptacle 190 may be arranged directly above the die attach region 302 along the y-axis or vertical axis (vertical relative to the orientation of the power package 100 as illustrated). In aspects, the receptacle 190 may be arranged directly above the die attach region 302 along an axis perpendicular to a surface of the power substrate 300 supporting the one or more power devices 200.

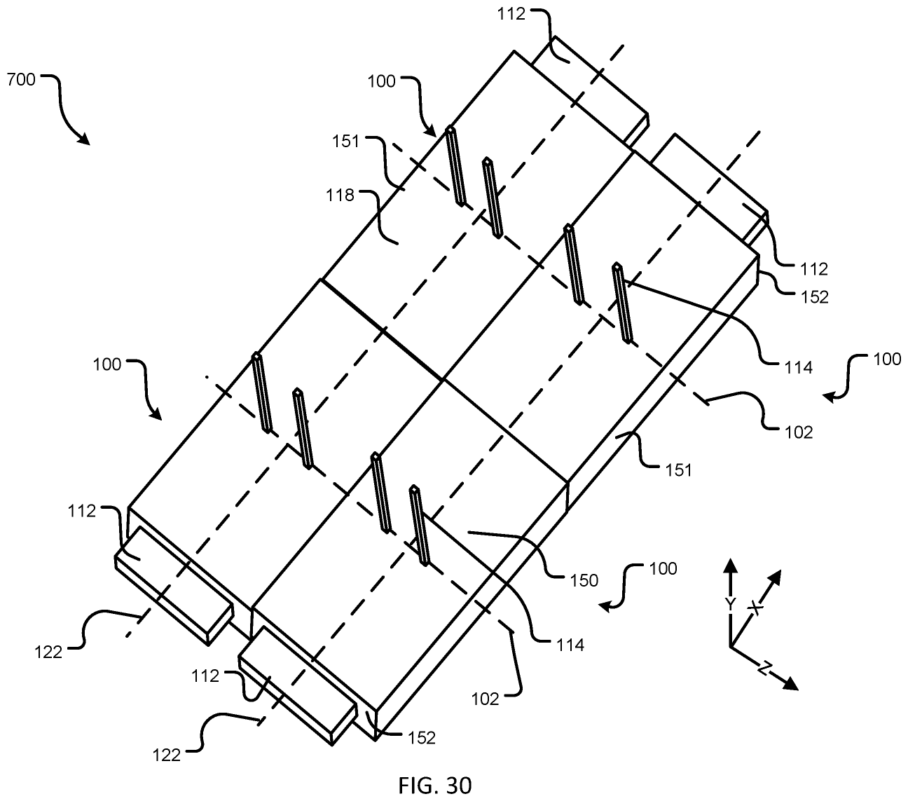

FIG. 30 illustrates a top side perspective view of a combined configuration of multiple implementations of the power package according to aspects of the disclosure.

In particular, FIG. 30 illustrates a top side perspective view of a combined configuration 700 of multiple implementations of the power package 100 according to aspects of the disclosure. The aspects of the power package 100 illustrated in FIG. 30 may optionally be implemented in any other aspects described herein. Moreover, other aspects described herein may optionally be implemented in the power package 100 of FIG. 30.

In aspects, the power package 100 may be configured as a single piece construction to form the combined configuration 700. In aspects, the disclosed power electronics package may be joined to multiple implementations of the power package 100 combined into a single module to form the combined configuration 700. In aspects, the power package 100 may be configured 2×2=4 packages combined into a power module to form the combined configuration 700. In aspects, the combined configuration 700 may include four implementations of the power package 100 added as two in a row and two in parallel as single module.

With reference to FIG. 30, each of the implementation of the power package 100 may include the various features of the power package 100 as previously described herein. For example, the signal contacts 114 and associated arrangement with respect to the contact lateral axis 102, the longitudinal contact axis 122, the power contacts 112, though 150, the power substrate 300 and the die attach region 302 (illustrated in FIG. 4 and FIG. 5), and/or the like.

In aspects particular aspects of the power package 100, the receptacle 190, the signal contacts 114, and/or an additional implementation of the signal contacts 114 may be communicate signals for current sensing. The current sensing may be implemented using a current sensor implemented by the power package 100.

In aspects particular aspects of the power package 100, the receptacle 190, the signal contacts 114, and/or an additional implementation of the signal contacts 114 may be communicate signals for voltage sensing. The voltage sensing may be implemented using a voltage sensor implemented by the power package 100.

In aspects particular aspects of the power package 100, the receptacle 190, the signal contacts 114, and/or an additional implementation of the signal contacts 114 may be communicate signals for temperature sensing. The temperature sensing may be implemented using a temperature sensor implemented by the power package 100.

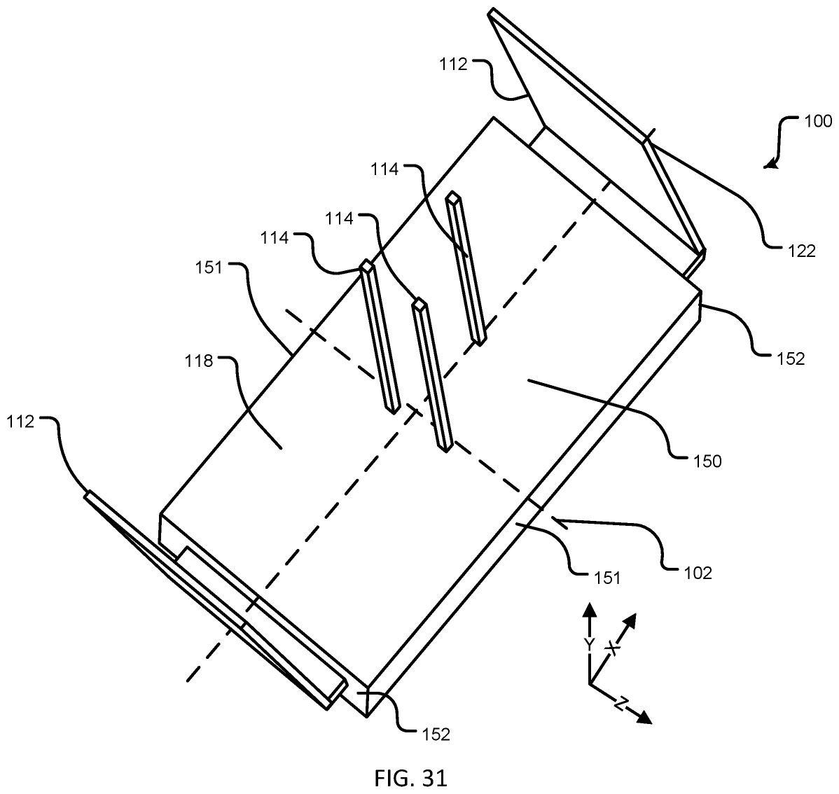

FIG. 31 illustrates a top side perspective view of a power package according to aspects of the disclosure.

In particular, FIG. 31 illustrates a top side perspective view of the power package 100 according to aspects of the disclosure. The aspects of the power package 100 illustrated in FIG. 31 may optionally be implemented in any other aspects described herein. Moreover, other aspects described herein may optionally be implemented in the power package 100 of FIG. 31.

With reference to FIG. 31, the power package 100 may include the various features of the power package 100 as previously described herein. Further, the FIG. 31 implementation of the power package 100 illustrates an additional implementation of the signal contacts 114. Additionally, the FIG. 31 implementation of the power package 100 illustrates an alternative implementation of the power contacts 112.

In aspects, the additional implementation of the signal contacts 114 may be communicate signals for current sensing, voltage sensing, temperature sensing and/or the like.

The power package 100 may include the one or more power devices 200 implemented as power semiconductor devices, including MOSFETs, IGBTs, diodes, and/or the like, arranged into a variety of circuit topologies. The power package 100 may include multiple devices in parallel and arranged into multiple switch positions. Aspects of the power package 100 may serve many functions including: Electrical interconnection, Electrical isolation, Heat transfer, Mechanical structure, Protection of the devices from environmental contamination and moisture, External electrical and thermal connection interfaces, Compliance with safety standards such as voltage creepage and clearance distances, and/or the like.

The power contacts 112 of the power package 100 may be configured to be wide, flat tabs on opposing sides of the power package 100. In particular, a width of the power contacts 112 may extend along the z-axis illustrated in FIG. 1. In aspects, the width of the power contacts 112 may be 60%-100% of a width of the power package 100, 60%-70% of a width of the power package 100, 70%-80% of a width of the power package 100, 80%-90% of a width of the power package 100, or 90%-100% of a width of the power package 100. In aspects, the power contacts 112 may be structured and arranged to have at least in part a flat portion in a plane of the x-axis and z-axis. The flat portion of the power contacts 112 may form a contact to other components, external components, and/or the like.

In aspects, the power contacts 112 may be configured to be electrically and mechanically connect to another implementation of the power package 100, a bus bar, and/or the like. In aspects, the power contacts 112 of the power package 100 may be configured to be electrically and mechanically connected to another component, such as a system, an application component, an application device, a wire, a clipped connection, and/or the like. The electrical and mechanical connections between the power contacts 112 and the another component may be implemented through a number of structures, methods, and/or the like. In aspects, the electrical and mechanical connections between the power contacts 112 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

In aspects, the signal contacts 114 of the power package 100 may be configured to be electrically and mechanically connected to another component, such as a gate driver, a gate driver printed circuit board (PCB), a wire, a clipped connection, and/or the like. The electrical and mechanical connections between the signal contacts 114 and the another component may be implemented through a number of structures, methods, and/or the like. In aspects, the electrical and mechanical connections between the signal contacts 114 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

In aspects, the power package 100 may be configured on a backside thereof with a thermal pad. The thermal pad may be configured as an exposed metal thermal pad. Further, the thermal pad may be configured with a large surface to thermally and mechanically attach to another component. The surface of the thermal pad may be configured to facilitate the removal of waste heat from conduction, switching, package resistive losses, and/or the like from the power package 100.

Additionally, the thermal pad may be configured to be attached via a connection to another component. The connection of the thermal pad to another component may be implemented by sintering, soldering, conductive epoxy, thermal paste, and/or the like. In this regard, the thermal pad may be configured to form the connection to another component utilizing one or more of these processes.

In aspects, the assembly 118 of the power package 100 may comprise a dielectric compound, a dielectric mold compound, a mold compound, a housing, a case, and/or the like. The assembly 118 may surround one or more components of the power package 100, a majority the components of the power package 100, all of the components of the power package 100 with the exception of portions of the power contacts 112, the signal contacts 114, the thermal pad, and/or the like. The assembly 118 may be configured, structured, and/or arranged with the power package 100 to provide electrical isolation, voltage safety distances, mechanical support to the internal layout and power semiconductor devices, and/or the like.

In aspects, the power package 100 may be configured with circuit topologies implementing one or more implementations of the power package 100. In this regard, arrangements of one or more implementations of the power package 100 may be configured as single positions and bridge legs, by themselves or with many in parallel, can achieve any of the circuit topologies described herein at any number of various scalable output power levels.

For example, parallel implementations of the power package 100 along the z-axis. In aspects, the parallel implementations of the power package 100 may be electrically connected at corresponding implementations of the power contacts 112 (not shown). Further, there may be any number of parallel implementations of the power package 100 along the x-axis.

In aspects of the disclosure, the power package 100 may be configured as a type of package that may be referred to as an ‘over-molded power module.’ In aspects, during manufacture multiple implementations of the power package 100 may be assembled on a patterned lead frame array, encapsulated with a mold compound or similar composite dielectric material, singulated from the lead frame array, and finally the electrical contacts are formed into shape. Often, multiple parts of the power package 100 may be fabricated on a single lead frame to maximize throughput. The processes of manufacturing the power package 100 and the various configurations of the power package 100 described herein may be highly compatible with serial processing in an automated manufacturing line.

In aspects, the one or more power devices 200 implemented by the power package 100 may be configured as power devices that may be configured and/or implemented as power semiconductor switches. In aspects, the power semiconductor switches implemented by the power package 100 may be sized to minimize a device area for a given power requirement.

In aspects, the power package 100 may implement one or more device attaches. In aspects, the one or more device attaches may comprise a material for attaching the one or more power devices 200 to the power substrate 300. The material of the one or more device attaches may be selected and/or implemented to (1) maximize thermal performance, (2) minimize cost, and/or the like.

In aspects, the power substrate 300 implemented by the power package 100 may comprise a material. The material of the power substrate 300 may be selected and/or implemented to (1) maximize thermal performance, (2) maximize reliability, (3) minimize cost, and/or the like.

Moreover, the power package 100 may be implemented in numerous circuit topologies including a single switch configuration, half bridge configuration, full bridge configuration, three phase bridge configuration (also called a six pack), buck configuration, boost configuration, buck-boost configuration, ćuk configuration, a common source configuration, a common drain configuration, a neutral point clamp configuration, and/or the like. Applications of the power package 100 may include a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, motor drives, solar inverters, circuit breakers, protection circuits, DC-DC converters, and/or the like.

Accordingly, the disclosure has set forth power electronics packages implementing layouts, structures, and/or configurations that can operate commensurate with the high level performance of the power devices implemented by the power electronics packages.

The following are a number of nonlimiting EXAMPLES of aspects of the disclosure.

One EXAMPLE: a power package that includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes where the signal contacts are configured on the top surface, in the top surface, and/or to extend from the top surface. The power package furthermore includes where the signal contacts are arranged in a middle section of the top surface between the second sides.

The above-noted EXAMPLE may further include any one or a combination of more than one of the following EXAMPLES:

The power package includes where the signal contacts are arranged in a middle section of the top surface between the first sides. The power package also includes where the signal contacts are arranged in a middle section of the top surface between the power contacts. The power package further includes where the signal contacts are arranged above the power substrate. The power package in addition includes where the power substrate may include a die attach region where the one or more power devices are arranged on a surface of the power substrate; and where the signal contacts are arranged above the die attach region of the one or more power devices. The power package moreover includes where the signal contacts are arranged on a contact lateral axis that extends between the first sides of the power package; and where the contact lateral axis is parallel to a lateral center axis of the power package. The power package also includes where the contact lateral axis is offset from a center lateral axis of the power package. The power package further includes where the signal contacts are arranged adjacent a longitudinal contact axis of the power package that extends between the second sides. The power package in addition includes where the longitudinal contact axis is offset from a center longitudinal axis of the power package. The power package moreover includes where the signal contacts are arranged on a longitudinal contact axis that extends between the second sides of the power package; and where the signal contacts are arranged adjacent a contact lateral axis. The power package also includes where the contact lateral axis is offset from a center lateral axis of the power package. The power package further includes where the longitudinal contact axis is offset from a center longitudinal axis of the power package. The power package in addition includes may include signal interconnections configured to connect the signal contacts to respective connections on the one or more power devices to provide signals to the one or more power devices. The power package moreover includes where the signal interconnections each have a similar length from the signal contacts to the one or more power devices, where a similar length is within 0%-20% in length. The power package also includes where the signal interconnections configured as gate interconnections each have a similar length from the signal contacts to the one or more power devices, where a similar length is within 0%-20% in length. The power package further includes where the signal interconnections configured as kelvin source interconnections each have a similar length from the signal contacts to the one or more power devices, where a similar length is within 0%-20% in length. The power package in addition includes where the power package has an overall gate-loop inductance that is generated based on a construction and configuration of the signal contacts and/or the signal interconnections; and where the signal contacts and/or the signal interconnections are constructed and configured to have a similar overall gate-loop inductance, where a similar overall gate-loop inductance is within 0%-6% in inductance. The power package moreover includes where the signal contacts are arranged and attached to the top surface of the assembly. The power package also includes where the signal contacts are at least partially within the assembly. The power package further includes where the assembly is configured with apertures for the signal contacts; and where the signal contacts are at least partially arranged within apertures in the assembly. The power package in addition includes where the signal contacts are configured to implement at least a source kelvin terminal and a gate terminal. The power package moreover includes where the signal contacts, and/or an additional implementation of the signal contacts are configured to communicate signals for current sensing, voltage sensing, and/or temperature sensing. The power package also includes where the signal contacts are configured as at least gate and kelvin-source signal contacts. The power package further includes where the signal contacts are configured as pin connectors. The power package in addition includes where the signal contacts are configured as a receptacle. The power package moreover includes where the receptacle is arranged on a longitudinal contact axis of the power package and on a contact lateral axis of the power package. The power package also includes where the contact lateral axis is offset from a center lateral axis of the power package. The power package further includes where the longitudinal contact axis is offset from a center longitudinal axis of the power package. The power package in addition includes where the receptacle is configured with press-fit technology. The power package moreover includes where the receptacle is furth configured to communicate signals for current sensing, voltage sensing, and/or temperature sensing. The power package also includes where the signal contacts and/or an additional implementation of the signal contacts are configured to communicate signals for current sensing, voltage sensing, and/or temperature sensing. The power package further includes where at least one of the signal contacts is configured as a true source kelvin signal connection. The power package in addition includes may include a combined configuration having multiple implementations of the power package. The power package moreover includes where the one or more power devices may include one or more MOSFETS, IGBTS, diodes, and/or JFETS.

One EXAMPLE: a power package that includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes where the power substrate may include a die attach region where the one or more power devices are arranged on a surface of the power substrate. The power package furthermore includes where the signal contacts are arranged above the die attach region of the one or more power devices.

The above-noted EXAMPLE may further include any one or a combination of more than one of the following EXAMPLES:

The power package includes where the signal contacts are arranged in a middle section of the top surface between the first sides. The power package also includes where the signal contacts are arranged in a middle section of the top surface between the power contacts. The power package further includes where the signal contacts are arranged above the power substrate. The power package in addition includes where the signal contacts are configured to extend from the top surface; and where the signal contacts are arranged in a middle section of the top surface between the second sides. The power package moreover includes where the signal contacts are arranged on a contact lateral axis that extends between the first sides of the power package; and where the contact lateral axis is parallel to a lateral center axis of the power package. The power package also includes where the contact lateral axis is offset from a center lateral axis of the power package. The power package further includes where the signal contacts are arranged adjacent a longitudinal contact axis of the power package that extends between the second sides. The power package in addition includes where the longitudinal contact axis is offset from a center longitudinal axis of the power package. The power package moreover includes where the signal contacts are arranged on a longitudinal contact axis that extends between the second sides of the power package; and where the signal contacts are arranged adjacent a contact lateral axis. The power package also includes where the contact lateral axis is offset from a center lateral axis of the power package. The power package further includes where the longitudinal contact axis is offset from a center longitudinal axis of the power package. The power package in addition includes may include signal interconnections configured to connect the signal contacts to respective connections on the one or more power devices to provide signals to the one or more power devices. The power package moreover includes where the signal interconnections each have a similar length from the signal contacts to the one or more power devices, where a similar length is within 0%-20% in length. The power package also includes where the signal interconnections configured as gate interconnections each have a similar length from the signal contacts to the one or more power devices, where a similar length is within 0%-20% in length. The power package further includes where the signal interconnections configured as kelvin source interconnections each have a similar length from the signal contacts to the one or more power devices, where a similar length is within 0%-20% in length. The power package in addition includes where the power package has an overall gate-loop inductance that is generated based on a construction and configuration of the signal contacts and/or the signal interconnections; and where the signal contacts and/or the signal interconnections are constructed and configured to have a similar overall gate-loop inductance, where a similar overall gate-loop inductance is within 0%-6% in inductance. The power package moreover includes where the signal contacts are arranged and attached to the top surface of the assembly. The power package also includes where the signal contacts are at least partially within the assembly. The power package further includes where the assembly is configured with apertures for the signal contacts; and where the signal contacts are at least partially arranged within apertures in the assembly. The power package in addition includes where the signal contacts are configured to implement at least a source kelvin terminal and a gate terminal. The power package moreover includes where the signal contacts, and/or an additional implementation of the signal contacts are configured to communicate signals for current sensing, voltage sensing, and/or temperature sensing. The power package also includes where the signal contacts are configured as at least gate and kelvin-source signal contacts. The power package further includes where the signal contacts are configured as pin connectors. The power package in addition includes where the signal contacts are configured as a receptacle. The power package moreover includes where the receptacle is arranged on a longitudinal contact axis of the power package and on a contact lateral axis of the power package. The power package also includes where the contact lateral axis is offset from a center lateral axis of the power package. The power package further includes where the longitudinal contact axis is offset from a center longitudinal axis of the power package. The power package in addition includes where the receptacle is configured with press-fit technology. The power package moreover includes where the receptacle is furth configured to communicate signals for current sensing, voltage sensing, and/or temperature sensing. The power package also includes where the signal contacts and/or an additional implementation of the signal contacts are configured to communicate signals for current sensing, voltage sensing, and/or temperature sensing. The power package further includes where at least one of the signal contacts is configured as a true source kelvin signal connection. The power package in addition includes may include a combined configuration having multiple implementations of the power package. The power package moreover includes where the one or more power devices may include one or more MOSFETS, IGBTS, diodes, and/or JFETS.

One EXAMPLE: a power package that includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes signal interconnections configured to connect the signal contacts to respective connections on the one or more power devices to provide signals to the one or more power devices. The power package furthermore includes where the power package has an overall gate-loop inductance that is generated based on a construction and configuration of the signal contacts and/or the signal interconnections. The power package in addition includes where the signal contacts and/or the signal interconnections are constructed and configured to have a similar overall gate-loop inductance, where a similar overall gate-loop inductance is within 0%-6% of the overall gate loop in inductance.

The above-noted EXAMPLE may further include any one or a combination of more than one of the following EXAMPLES:

The power package includes where the signal contacts are arranged in a middle section of the top surface between the first sides. The power package also includes where the signal contacts are arranged in a middle section of the top surface between the power contacts. The power package further includes where the signal contacts are arranged above the power substrate. The power package in addition includes where the signal contacts are configured to extend from the top surface; and where the signal contacts are arranged in a middle section of the top surface between the second sides. The power package moreover includes where the signal contacts are arranged on a contact lateral axis that extends between the first sides of the power package; and where the contact lateral axis is parallel to a lateral center axis of the power package. The power package also includes where the contact lateral axis is offset from a center lateral axis of the power package. The power package further includes where the signal contacts are arranged adjacent a longitudinal contact axis of the power package that extends between the second sides. The power package in addition includes where the longitudinal contact axis is offset from a center longitudinal axis of the power package. The power package moreover includes where the signal contacts are arranged on a longitudinal contact axis that extends between the second sides of the power package; and where the signal contacts are arranged adjacent a contact lateral axis. The power package also includes where the contact lateral axis is offset from a center lateral axis of the power package. The power package further includes where the longitudinal contact axis is offset from a center longitudinal axis of the power package. The power package in addition includes where the signal interconnections each have a similar length from the signal contacts to the one or more power devices, where a similar length is within 0%-20% in length. The power package moreover includes where the signal interconnections configured as gate interconnections each have a similar length from the signal contacts to the one or more power devices, where a similar length is within 0%-20% in length. The power package also includes where the signal interconnections configured as kelvin source interconnections each have a similar length from the signal contacts to the one or more power devices, where a similar length is within 0%-20% in length. The power package further includes where the power substrate may include a die attach region where the one or more power devices are arranged on a surface of the power substrate; and where the signal contacts are arranged above the die attach region of the one or more power devices. The power package in addition includes where the signal contacts are arranged and attached to the top surface of the assembly. The power package moreover includes where the signal contacts are at least partially within the assembly. The power package also includes where the assembly is configured with apertures for the signal contacts; and where the signal contacts are at least partially arranged within apertures in the assembly. The power package further includes where the signal contacts are configured to implement at least a source kelvin terminal and a gate terminal. The power package in addition includes where the signal contacts, and/or an additional implementation of the signal contacts are configured to communicate signals for current sensing, voltage sensing, and/or temperature sensing. The power package moreover includes where the signal contacts are configured as at least gate and kelvin-source signal contacts. The power package also includes where the signal contacts are configured as pin connectors. The power package further includes where the signal contacts are configured as a receptacle. The power package in addition includes where the receptacle is arranged on a longitudinal contact axis of the power package and on a contact lateral axis of the power package. The power package moreover includes where the contact lateral axis is offset from a center lateral axis of the power package. The power package also includes where the longitudinal contact axis is offset from a center longitudinal axis of the power package. The power package further includes where the receptacle is configured with press-fit technology. The power package in addition includes where the receptacle is furth configured to communicate signals for current sensing, voltage sensing, and/or temperature sensing. The power package moreover includes where the signal contacts and/or an additional implementation of the signal contacts are configured to communicate signals for current sensing, voltage sensing, and/or temperature sensing. The power package also includes where at least one of the signal contacts is configured as a true source kelvin signal connection. The power package further includes may include a combined configuration having multiple implementations of the power package. The power package in addition includes where the one or more power devices may include one or more MOSFETS, IGBTS, diodes, and/or JFETS.

One EXAMPLE: a power package that includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes signal interconnections configured to connect the signal contacts to respective connections on the one or more power devices to provide signals to the one or more power devices. The power package furthermore includes where the signal interconnections each have a similar length from the signal contacts to the one or more power devices, where a similar length is within 0%-20% in length.

The above-noted EXAMPLE may further include any one or a combination of more than one of the following EXAMPLES:

The power package includes where the signal contacts are arranged in a middle section of the top surface between the first sides. The power package also includes where the signal contacts are arranged in a middle section of the top surface between the power contacts. The power package further includes where the signal contacts are arranged above the power substrate. The power package in addition includes where the signal contacts are configured to extend from the top surface; and where the signal contacts are arranged in a middle section of the top surface between the second sides. The power package moreover includes where the signal contacts are arranged on a contact lateral axis that extends between the first sides of the power package; and where the contact lateral axis is parallel to a lateral center axis of the power package. The power package also includes where the contact lateral axis is offset from a center lateral axis of the power package. The power package further includes where the signal contacts are arranged adjacent a longitudinal contact axis of the power package that extends between the second sides. The power package in addition includes where the longitudinal contact axis is offset from a center longitudinal axis of the power package. The power package moreover includes where the signal contacts are arranged on a longitudinal contact axis that extends between the second sides of the power package; and where the signal contacts are arranged adjacent a contact lateral axis. The power package also includes where the contact lateral axis is offset from a center lateral axis of the power package. The power package further includes where the longitudinal contact axis is offset from a center longitudinal axis of the power package. The power package in addition includes where the power package has an overall gate-loop inductance that is generated based on a construction and configuration of the signal contacts and/or the signal interconnections; and where the signal contacts and/or the signal interconnections are constructed and configured to have a similar overall gate-loop inductance, where a similar overall gate-loop inductance is within 0%-6% in inductance. The power package moreover includes where the signal interconnections configured as gate interconnections each have a similar length from the signal contacts to the one or more power devices, where a similar length is within 0%-20% in length. The power package also includes where the signal interconnections configured as kelvin source interconnections each have a similar length from the signal contacts to the one or more power devices, where a similar length is within 0%-20% in length. The power package further includes where the power substrate may include a die attach region where the one or more power devices are arranged on a surface of the power substrate; and where the signal contacts are arranged above the die attach region of the one or more power devices. The power package in addition includes where the signal contacts are arranged and attached to the top surface of the assembly. The power package moreover includes where the signal contacts are at least partially within the assembly. The power package also includes where the assembly is configured with apertures for the signal contacts; and where the signal contacts are at least partially arranged within apertures in the assembly. The power package further includes where the signal contacts are configured to implement at least a source kelvin terminal and a gate terminal. The power package in addition includes where the signal contacts, and/or an additional implementation of the signal contacts are configured to communicate signals for current sensing, voltage sensing, and/or temperature sensing. The power package moreover includes where the signal contacts are configured as at least gate and kelvin-source signal contacts. The power package also includes where the signal contacts are configured as pin connectors. The power package further includes where the signal contacts are configured as a receptacle. The power package in addition includes where the receptacle is arranged on a longitudinal contact axis of the power package and on a contact lateral axis of the power package. The power package moreover includes where the contact lateral axis is offset from a center lateral axis of the power package. The power package also includes where the longitudinal contact axis is offset from a center longitudinal axis of the power package. The power package further includes where the receptacle is configured with press-fit technology. The power package in addition includes where the receptacle is furth configured to communicate signals for current sensing, voltage sensing, and/or temperature sensing. The power package moreover includes where the signal contacts and/or an additional implementation of the signal contacts are configured to communicate signals for current sensing, voltage sensing, and/or temperature sensing. The power package also includes where at least one of the signal contacts is configured as a true source kelvin signal connection. The power package further includes may include a combined configuration having multiple implementations of the power package. The power package in addition includes where the one or more power devices may include one or more MOSFETS, IGBTS, diodes, and/or JFETS.

One EXAMPLE: a power package includes a power substrate. The power package also includes one or more power devices arranged on the power substrate. The power package furthermore includes an assembly having a top surface, first sides, and second sides. The power package in addition includes power contacts. The power package moreover includes signal contacts. The power package also includes signal interconnections configured to connect the signal contacts to respective connections on the one or more power devices to provide signals to the one or more power devices. The power package furthermore includes where the signal contacts and/or the signal interconnections are constructed and configured to have a similar overall gate-loop inductance, where a similar overall gate-loop inductance is within 3 nH.

The above-noted EXAMPLE may further include any one or a combination of more than one of the following EXAMPLES:

The power package includes where the signal contacts are arranged in a middle section of the top surface between the first sides. The power package also includes where the signal contacts are arranged in a middle section of the top surface between the power contacts. The power package further includes where the signal contacts are arranged above the power substrate. The power package in addition includes where the signal contacts are configured to extend from the top surface; and where the signal contacts are arranged in a middle section of the top surface between the second sides. The power package moreover includes where the signal contacts are arranged on a contact lateral axis that extends between the first sides of the power package; and where the contact lateral axis is parallel to a lateral center axis of the power package. The power package also includes where the contact lateral axis is offset from a center lateral axis of the power package. The power package further includes where the signal contacts are arranged adjacent a longitudinal contact axis of the power package that extends between the second sides. The power package in addition includes where the longitudinal contact axis is offset from a center longitudinal axis of the power package. The power package moreover includes where the signal contacts are arranged on a longitudinal contact axis that extends between the second sides of the power package; and where the signal contacts are arranged adjacent a contact lateral axis. The power package also includes where the contact lateral axis is offset from a center lateral axis of the power package. The power package further includes where the longitudinal contact axis is offset from a center longitudinal axis of the power package. The power package in addition includes where the signal interconnections each have a similar length from the signal contacts to the one or more power devices, where a similar length is within 0% 20% in length. The power package moreover includes where the power package has an overall gate-loop inductance that is generated based on a construction and configuration of the signal contacts and/or the signal interconnections; and where the signal contacts and/or the signal interconnections are constructed and configured to have a similar overall gate-loop inductance, where a similar overall gate-loop inductance is within 0% 6% in inductance. The power package also includes where the signal interconnections configured as gate interconnections each have a similar length from the signal contacts to the one or more power devices, where a similar length is within 0% 20% in length. The power package further includes where the signal interconnections configured as kelvin source interconnections each have a similar length from the signal contacts to the one or more power devices, where a similar length is within 0% 20% in length. The power package in addition includes where the power substrate may include a die attach region where the one or more power devices are arranged on a surface of the power substrate; and where the signal contacts are arranged above the die attach region of the one or more power devices. The power package moreover includes where the signal contacts are arranged and attached to the top surface of the assembly. The power package also includes where the signal contacts are at least partially within the assembly. The power package further includes where the assembly is configured with apertures for the signal contacts; and where the signal contacts are at least partially arranged within apertures in the assembly. The power package in addition includes where the signal contacts are configured to implement at least a source kelvin terminal and a gate terminal. The power package moreover includes where the signal contacts, and/or an additional implementation of the signal contacts are configured to communicate signals for current sensing, voltage sensing, and/or temperature sensing. The power package also includes where the signal contacts are configured as at least gate and kelvin-source signal contacts. The power package further includes where the signal contacts are configured as pin connectors. The power package in addition includes where the signal contacts are configured as a receptacle. The power package moreover includes where the receptacle is arranged on a longitudinal contact axis of the power package and on a contact lateral axis of the power package. The power package also includes where the contact lateral axis is offset from a center lateral axis of the power package. The power package further includes where the longitudinal contact axis is offset from a center longitudinal axis of the power package. The power package in addition includes where the receptacle is configured with press-fit technology. The power package moreover includes where the receptacle is furth configured to communicate signals for current sensing, voltage sensing, and/or temperature sensing. The power package also includes where the signal contacts and/or an additional implementation of the signal contacts are configured to communicate signals for current sensing, voltage sensing, and/or temperature sensing. The power package further includes where at least one of the signal contacts is configured as a true source kelvin signal connection. The power package in addition includes may include a combined configuration having multiple implementations of the power package. The power package moreover includes where the one or more power devices may include one or more MOSFETS, IGBTS, diodes, and/or JFETS.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A power package comprising:
a power substrate;
one or more power devices arranged on the power substrate;
an assembly comprising a top surface, first sides, and second sides;
power contacts; and
signal contacts,
wherein the signal contacts are configured on the top surface, in the top surface, and/or to extend from the top surface; and
wherein the signal contacts are arranged in a middle section of the top surface between the second sides.

2. The power package according to claim 1 wherein the signal contacts are arranged in a middle section of the top surface between the first sides.

3. The power package according to claim 1 wherein the signal contacts are arranged in a middle section of the top surface between the power contacts.

4. The power package according to claim 1 wherein the signal contacts are arranged above the power substrate.

5. The power package according to claim 1
wherein the power substrate comprises a die attach region where the one or more power devices are arranged on a surface of the power substrate; and
wherein the signal contacts are arranged above the die attach region of the one or more power devices.

6. The power package according to claim 1
wherein the signal contacts are arranged on a contact lateral axis that extends between the first sides of the power package; and
wherein the contact lateral axis is parallel to a lateral center axis of the power package.

7.-9. (canceled)

10. The power package according to claim 1
wherein the signal contacts are arranged on a longitudinal contact axis that extends between the second sides of the power package; and
wherein the signal contacts are arranged adjacent a contact lateral axis.

11.-12. (canceled)

13. The power package according to claim 1 further comprising signal interconnections configured to connect the signal contacts to respective connections on the one or more power devices to provide signals to the one or more power devices.

14. The power package according to claim 13 wherein the signal interconnections each have a similar length from the signal contacts to the one or more power devices, where a similar length is within 0%-20% in length.

15.-16. (canceled)

17. The power package according to claim 13
wherein the power package has an overall gate-loop inductance that is generated based on a construction and configuration of the signal contacts and/or the signal interconnections; and
wherein the signal contacts and/or the signal interconnections are constructed and configured to have a similar overall gate-loop inductance, where a similar overall gate-loop inductance is within 0%-6% in inductance.

18. The power package according to claim 13
wherein the power package has an overall gate-loop inductance that is generated based on a construction and configuration of the signal contacts and/or the signal interconnections; and
wherein the signal contacts and/or the signal interconnections are constructed and configured to have a similar overall gate-loop inductance, where a similar overall gate-loop inductance is within 3 nH.

19.-21. (canceled)

22. The power package according to claim 1 wherein the signal contacts are configured to implement at least a source kelvin terminal and a gate terminal.

23.-25. (canceled)

26. The power package according to claim 1 wherein the signal contacts are configured as a receptacle.

27.-35. (canceled)

36. A power package comprising:
a power substrate;
one or more power devices arranged on the power substrate;
an assembly comprising a top surface, first sides, and second sides;
power contacts; and
signal contacts,
wherein the power substrate comprises a die attach region where the one or more power devices are arranged on a surface of the power substrate; and
wherein the signal contacts are arranged above the die attach region of the one or more power devices.

37. The power package according to claim 36 wherein the signal contacts are arranged in a middle section of the top surface between the first sides.

38. The power package according to claim 36 wherein the signal contacts are arranged in a middle section of the top surface between the power contacts.

39. The power package according to claim 36 wherein the signal contacts are arranged above the power substrate.

40.-70. (canceled)

71. A power package comprising:
a power substrate;
one or more power devices arranged on the power substrate;
an assembly comprising a top surface, first sides, and second sides;
power contacts;
signal contacts; and
signal interconnections configured to connect the signal contacts to respective connections on the one or more power devices to provide signals to the one or more power devices,
wherein the power package has an overall gate-loop inductance that is generated based on a construction and configuration of the signal contacts and/or the signal interconnections; and
wherein the signal contacts and/or the signal interconnections are constructed and configured to have a similar overall gate-loop inductance, where a similar overall gate-loop inductance is within 0%-6% in inductance.

72. The power package according to claim 71
wherein the power package has an overall gate-loop inductance that is generated based on a construction and configuration of the signal contacts and/or the signal interconnections; and
wherein the signal contacts and/or the signal interconnections are constructed and configured to have a similar overall gate-loop inductance, where a similar overall gate-loop inductance is within 3 nH.

73. The power package according to claim 71 wherein the signal contacts are arranged in a middle section of the top surface between the first sides.

74. The power package according to claim 71 wherein the signal contacts are arranged in a middle section of the top surface between the power contacts.

75. The power package according to claim 71 wherein the signal contacts are arranged above the power substrate.

76. The power package according to claim 71
wherein the signal contacts are configured to extend from the top surface; and
wherein the signal contacts are arranged in a middle section of the top surface between the second sides.

77.-172. (canceled)
